(19) United States
(12) Patent Application Publication
(10) Pub. No.: US 2026/0147278 A1
(43) Pub. Date: May 28, 2026

(54) ORGANIC UNDERLAYER AND METHODS FOR EUV DOSE REDUCTION

(71) Applicant: Brewer Science, Inc., Rolla, MO (US)

(72) Inventors: Yubao Wang, Rolla, MO (US); Daniel Patrick Sweat, Rolla, MO (US); Stephen M. Grannemann, Rolla, MO (US)

(21) Appl. No.: 19/400,708

(22) Filed: Nov. 25, 2025

Related U.S. Application Data
(60) Provisional application No. 63/724,455, filed on Nov. 25, 2024.
(60) Provisional application No. 63/762,620, filed on Feb. 24, 2025.
(60) Provisional application No. 63/808,716, filed on May 20, 2025.

(51) Int. Cl. G03F 7/09; G03F 7/00; G03F 7/004

(52) U.S. Cl. CPC G03F 7/094; G03F 7/0043; G03F 7/0048; G03F 7/70033

(57) ABSTRACT

A method of forming a microelectronic structure on a substrate is disclosed. The method includes applying an underlayer forming composition to an uppermost intermediate layer of a lithography stack, if present, or to the substrate to form an underlayer. The underlayer forming composition includes a pre-ionic compound that generates an ionic compound, moiety, or both during post-application bake. The pre-ionic compound can include, for example, a copolymer having glycidyl methacrylate and 4-vinylpyridine. An EUV-sensitive photoresist comprising a metal-oxide is applied directly on an upper surface of the underlayer. EUV lithography is then performed. This method can be used to achieve dose reduction compared to prior art methods of EUV lithography using metal-oxide containing photoresists. Various underlayer forming compositions for performing EUV lithography using a metal-oxide-containing resist are also disclosed.

### CROSS-REFERENCE TO RELATED APPLICATIONS

The present application claims the priority benefit of U.S. Provisional Patent Application Ser. No. 63/724,455, filed Nov. 25, 2024, entitled ORGANIC UNDERLAYER AND METHODS OF EUV DOSE REDUCTION, the entirety of which is incorporated by reference herein. The present application also claims the priority benefit of U.S. Provisional Patent Application Ser. No. 63/808,716, filed May 20, 2025, entitled ORGANIC UNDERLAYER AND METHODS OF EUV DOSE REDUCTION, the entirety of which is incorporated by reference herein. The present application also claims the priority benefit of U.S. Provisional Patent Application Ser. No. 63/762,620, filed Feb. 24, 2025, entitled UNDERLAYER AND METHODS FOR EUV DOSE REDUCTION, the entirety of which is incorporated by reference herein.

### BACKGROUND

### Field

This invention relates in general to materials and methods for fabricating microelectronic structures using EUV (extreme ultraviolet) lithography.

### Description of Related Art

As the semiconductor industry continues to follow Moore's law, the demand for ever-decreasing feature sizes requires the use of thinner films to prevent pattern collapse. Extreme ultraviolet (EUV) exposure is expected to be the method of choice for single exposure lithography to achieve the required critical dimension (CD) targets of the 7-nm node and beyond. Unfortunately, EUV lithography has been hindered by problems, including stochastic effects and adhesion issues.

The demands in the semiconductor industry for advanced device manufacturing require materials and processes that enable high resolution, low defectivity, and a stable process window. EUV lithography has been deployed for the sub-20-nm half-pitch feature to achieve higher resolution and lower cost, compared to the multi-patterning immersion ArF. To get even higher resolution, high-numerical-aperture (NA) EUV and multi-patterning EUV lithography are expected to be applied in future nodes. Meanwhile, the development of photoresists suitable for EUV lithography remains critical. Chemically amplified resists (CARs) based on photoacids and organic polymers have been dominant in semiconductor industries for the past decade. However, CARs face challenges in minimizing the line width roughness (LWR), line edge roughness (LER), and resolution at sub-10-nm nodes, due to a large gyration radius of the polymer. The high photon shot noise at low doses in EUV lithography also limits the defect-free resolution of the CARs due to the stochastic effect.

Some efforts to improve the EUV lithography production process have been directed to photoresist improvements. One line of research has led to the development of metal oxide resists (MORs). MORs contain metal oxide complexes in their composition and are designed to absorb EUV photons more efficiently, produce higher contrast, and enable higher resolution than other types of EUV resists. Although MORs are very promising, many issues still hinder achievement of desired EUV lithography manufacturing objectives for pattern quality and throughput.

Recently, organometallic molecules and metal nanoclusters were also developed as alternatives for efficient EUV lithography. The incorporation of metal atoms provides several advantages over traditional organic CARs, like higher EUV absorption, larger quantum yield, smaller resist blur, and better etch resistance. Several commercial MORs have been developed as alternatives for CARs in next-generation nodes. Unlike CARs, which rely on acid diffusion and chemical amplification, MORs operate via a distinct activation and condensation mechanism during EUV exposure, enabling precise pattern formation with reduced variability.

The EUV lithography process is extremely expensive. Thus, any improvements to throughput would be extremely valuable. There are also problems with pattern quality including resolution, LWR, and LER. Underlayers are often used under the photoresist for various reasons, such as to improve adhesion between the resist and the layer on which it is applied. The interactions between an EUV photoresist and any layer immediately underneath it in a lithography stack are complex and varied throughout the lithography process. Efforts to reduce the EUV dose that is required often face a trade-off in that marginally sufficient dose exposure times (to push throughput as high as possible) typically result in resist profiles that are not as straight and clean as desired for advanced (i.e., very small) critical dimensions (CDs).

Spin-on underlayers have traditionally been used along with the CARs to improve sensitivity, LWR, stochastic failure, and process window in the EUV lithography. However, the fundamentally different chemistry of MORs poses unique challenges for underlayer design. This is because smaller organometallic molecules and metal clusters limit the physical entanglement and bonding of the underlayers. Nevertheless, it was noticed that underlayers have a significant impact in MOR EUV lithography regarding the process window, sensitivity, and defects. Spin-on underlayers act as a critical interface between the MOR resist and substrate, which improves resist compatibility, enhances activation, and mitigates defects during patterning.

Thus, despite tremendous efforts there remains a need for underlayers for EUV lithography that improve patterned resist profile while also enabling dose reduction for EUV lithography.

### SUMMARY

In one embodiment, the disclosure provides a method of forming a structure. The method comprises applying a composition to a stack so as to form an underlayer on the stack. The composition comprises a solvent system having one or both of the following dispersed or dissolved therein:
(1) about 5% by weight or more of an ionic compound, ionic moiety, or both, with the percentage by weight being based on the total solids in the composition taken as 100% by weight, wherein when the ionic compound or ionic moiety comprises

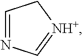

the following structure is not present

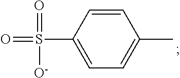

or
(2) a pre-ionic compound capable of generating (1) when heated.
   A metal oxide photoresist layer is formed on the underlayer, and at least a portion of the photoresist layer is subjected to EUV radiation.

In another embodiment, the disclosure provides a structure comprising a substrate having a surface. There is optionally one or more intermediate layers on the substrate surface, there being an uppermost intermediate layer on the substrate surface, if one or more intermediate layers are present. An underlayer is on the substrate surface, or on the uppermost intermediate layer, if present. The underlayer comprises one or both of:
(1) about 5% by weight or more of an ionic compound, ionic moiety, or both, said % by weight being based on the total weight of the underlayer taken as 100% by weight,
   wherein when said ionic moiety comprises

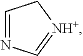

the following structure is not present

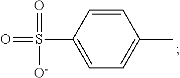

or
(2) a polymer network comprising tertiary amines reacted with respective displaceable electrophiles to form crosslinks, said tertiary amines including respective positively charged nitrogen atoms and said crosslinks including negatively charged oxygen atoms; and
   There is a metal oxide photoresist on the underlayer.

### BRIEF DESCRIPTION OF THE DRAWINGS

FIG. 1 is a schematic diagram (not to scale) showing one embodiment of a lithography stack and steps in one embodiment of a process for making a microelectronic structure;

FIG. 2 is a graph showing CD vs. dose for each of the EUV underlayers of Examples 18-21, as tested in Example 35;

FIG. 3 is a graph showing CD vs. dose for each of the EUV underlayers of Examples 25-29, as tested in Example 35;

FIG. 4 shows cross sectional scanning electron microscope (SEM) images of lines formed by EUV lithography as described in Example 35, using the underlayers of Examples 18-21 with a MOR photoresist;

FIG. 5 shows a line-space focus exposure matrix (FEM) of the underlayer prepared in Example 38;

FIG. 6 shows a line-space FEM of the underlayer prepared in Example 39;

FIG. 7 shows a line-space FEM of the underlayer prepared in Example 40;

FIG. 8 is an FEM and SEM image of a sample wafer prepared and tested in Example 43;

FIG. 9 is an FEM of a sample wafer prepared and tested in Example 45;

FIG. 10 is an FEM and an SEM image of a sample wafer prepared and tested in Example 47;

FIG. 11 is an FEM of a sample wafer prepared and tested in Example 49;

FIG. 12 is an FEM of a sample wafer prepared and tested in Example 52;

FIG. 13 shows a line-space focus exposure matrix of Example 57, Part 1; and

FIG. 14 shows a line-space focus exposure matrix of Example 57, Part 2.

### DETAILED DESCRIPTION

The present disclosure is broadly concerned with compositions for forming underlayers and methods of using those compositions to form microelectronic structures.

### Compositions for Underlayer

Suitable compositions generally comprise one or more of a pre-ionic compound, ionic compound, ionic moiety dispersed or dissolved in a solvent system.

A. Ionic Compound and/or Ionic Moiety Generated During Bake

### 1. Pre-Ionic Compound

Suitable pre-ionic compounds are nonionic but are capable of generating an ionic compound, ionic moiety, or both upon exposure to heat, such as the heat applied during a post-application bake. That is, preferred such pre-ionic compounds will generate an ionic compound, ionic moiety, or both upon exposure to a temperature of about 100° C. to about 300° C., preferably from about 150° C. to about 250° C., and more preferably from about 200° C. to about 250° C. Suitable pre-ionic compounds are capable of generating the ionic compound, ionic moiety, or both after about 30 seconds to about 120 seconds, preferably from about 45 seconds to about 60 seconds to these temperatures. In some embodiments, the pre-ionic compound will generate the ionic compound, ionic moiety, or both upon exposure to about 205° C. for about 60 seconds.

a. Tertiary Amine and Displaceable Electrophile on Same Polymer

In some embodiments, the pre-ionic compound is a polymer comprising a first monomer comprising a tertiary amine (e.g., aromatic amine) and a second monomer comprising a displaceable electrophile. The displaceable electrophile preferably comprises an electrophilic species that can be displaced by the tertiary amine. Suitable displaceable electrophiles include epoxides, alkyl halides, or combinations thereof. Alkyl halides comprise a halogen chosen from one or more of chlorine, fluorine, bromine, iodine and are typically C₂ to C₁₀ alkyls.

Suitable first monomers include those chosen from vinylpyridine (including 2-vinylpyridine and 4-vinylpyridine), 2-(dimethylamino)ethyl methacrylate, 1-vinylimidazole, or combinations thereof.

Suitable second monomers comprising an epoxide include those chosen from glycidyl acrylate, glycidyl methacrylate, 4-glycidyloxystyrene, or combinations thereof.

Suitable second monomers comprising an alkyl halide include those chosen from 4-(chloromethyl)styrene, 2-iodomethacrylate, or combinations thereof.

b. Tertiary Amine and Displaceable Electrophile on Different Polymers

In the same or different embodiments, the pre-ionic compound is provided as two or more different types of polymer. That is, there are at least two pre-ionic compounds comprising a first polymer and a second polymer. The first polymer comprises a monomer that comprises a tertiary amine (e.g., aromatic amine), and the second polymer comprises a monomer that comprises a displaceable electrophile as described above.

Suitable first polymers, which can be a homopolymer or a copolymer, comprise monomers chosen from vinylpyridine (including 2-vinylpyridine and 4-vinylpyridine), 2-(dimethylamino)ethyl methacrylate, 1-vinylimidazole, or combinations thereof. Suitable second polymers, which can also be a homopolymer or a copolymer, comprise a monomer chosen from glycidyl acrylate, glycidyl methacrylate, 4-glycidyloxystyrene, or combinations thereof.

c. Third Monomer

Regardless of which pre-ionic compound embodiment is utilized, in some embodiments it is preferred that a third monomer is included. Preferably, the third monomer does not include a tertiary amine or a displaceable electrophile. The third monomer can be included as a comonomer on the polymer that includes a first monomer comprising a tertiary amine and a second monomer comprising a displaceable electrophile. Additionally or alternatively, the third monomer can be a comonomer in one or both of the first or second polymer in embodiments where the tertiary amine and displaceable electrophile are on different polymers. As yet a further option, the third monomer can be provided as part of a completely separate and different polymer and/or can simply be added in monomeric form.

Suitable third monomers include vinylic monomers, acrylic monomers, and/or styrenic monomers. Exemplary third monomers include those chosen from substituted and unsubstituted styrene-containing monomers, methyl acrylate, hydroxyethyl methacrylate, hydroxyethyl acrylate, hydroxypropyl methacrylate, benzyl methacrylate, n-butyl methacrylate, methyl methacrylate, tert-butyl methacrylate, 2-(dimethylamino)ethyl methacrylate, N-(butoxymethyl)acrylamide, or combinations thereof. Examples of substituted styrene-containing monomers include those chosen from styrene, pentafluorostyrene, 4-methylstyrene, 4-tert-butylstyrene, 4-methoxystyrene 4-fluorostyrene, 4-chlorostyrene, 4-bromostyrene, 4-iodostyrene, or combinations thereof.

Regardless of which of the foregoing polymers are chosen, the number average molecular weight (Mn) of the polymer is preferably about 2,000 g/mol to about 30,000 g/mol, and more preferably about 4,000 g/mol to about 25,000 g/mol. The weight-average molecular weight (Mw) range (as measured by gel permeation chromatography) of the polymer is preferably about 3,000 g/mol to about 100,000 g/mol, and more preferably about 6,000 g/mol to about 70,000 g/mol.

d. Monomer and Polymer Levels

Regardless of the chosen polymers and monomers, it is preferred that the monomers comprising a displaceable electrophile are included at a level of about 3 mol % to about 50 mol %, preferably about 3 mol % to about 35 mol %, and more preferably about 5 mol % to about 35 mol %, with the mol % being based on the total of all monomers present on all polymers used in the underlayer composition being taken as 100 mol %.

In the same or different embodiments, it is preferred that the monomers comprising a tertiary amine are included at a level of about 3 mol % to about 20 mol %, preferably about 3 mol % to about 10 mol %, and more preferably about 3 mol % to about 5 mol %, with the mol % being based on the total of all monomers present on all polymers used in the underlayer composition being taken as 100 mol %.

Additionally or alternatively, the molar ratio of tertiary amine to displaceable electrophile is typically about 2:1 to about 1:20, and more preferably about 1:2 to about 1:10.

When a third monomer is included (regardless of how it is provided), it is preferably included at a level of about 10 mol % to about 80 mol %, more preferably about 20 mol % to about 70 mol %, and even more preferably about 25 mol % to about 60 mol %, with the mol % being based on the total of all monomers present on all polymers used in the underlayer composition being taken as 100 mol %.

The total weight of all polymers present in the composition is typically about 50% to about 100% by weight, more preferably about 50% to about 95% by weight, and even more preferably about 60% to about 90% by weight, based upon the total weight of the solids in the composition taken as 100% by weight.

e. Polymer Synthesis

To synthesize the polymers described herein, the desired monomers are suitably charged to a stirred reactor with an appropriate polymerization solvent. Polymerization solvents include propylene glycol monomethyl ether acetate (“PGMEA”), propylene glycol methyl ether (“PGME”), acetone, propylene glycol ethyl ether (“PGEE”), cyclohexanone, ethyl lactate, 3-methyl-1,5-pentanediol, 1,2-propylene glycol, 1,3-propylene glycol, ethylene glycol, or mixtures thereof. An initiator, such as azobisisobutyronitrile (AIBN) is added to the reactor along with the monomers. Monomer percent solids in the reaction mixture are preferably about 10% to about 40%, and more preferably about 15% to about 35%, based on the combined weight of the reaction mixture (including monomers, catalysts, and solvent(s) taken as 100% by weight). The reactor is suitably heated to a temperature of about 55° C. to about 85° C., and preferably about 70° C. The reaction mixture is allowed to stir for about 8 hours to about 24 hours, and more preferably about 16 hours. The reaction is optionally performed in an inert atmosphere such as nitrogen.

### 2. Solvent System

Exemplary solvent systems include one or more solvents chosen from propylene glycol methyl ether acetate (PGMEA), propylene glycol methyl ether (PGME), propylene glycol ethyl ether (PGEE), propylene glycol n-propyl ether (PnP), ethyl lactate, cyclopentanone, cyclohexanone, gamma-butyrolactone (GBL), methyl isobutyl carbinol, 3-methyl-1,5-pentanediol, 1,2-propylene glycol, 1,3-propylene glycol, ethylene glycol, or mixtures thereof. Preferably, the solvent system has a boiling point of about 70° to about 200° C., and more preferably about 100° to about 150° C.

The solvent system is preferably utilized at a level of about 98% to about 99.99% by weight, more preferably about 99% to 99.9%, and even more preferably about 99.3% to about 99.8% by weight, based upon the total weight of the composition taken as 100% by weight. The compositions used to form the underlayer preferably comprise a solids content of about 0.1% to about 1% by weight solids, more preferably about 0.1% to about 0.8% by weight solids, and even more preferably about 0.1% to about 0.5% by weight solids, based upon the total weight of the composition taken as 100% by weight. In another embodiment, the solvent system is preferably utilized at a level of about 20% to about 99.99% by weight, more preferably about 80% to 99.9%, and even more preferably about 90% to about 99.9% by weight, based upon the total weight of the composition taken as 100% by weight. The compositions used to form the underlayer preferably comprise a solids content of about 0.01% to about 20% by weight solids, more preferably about 0.01% to about 10% by weight solids, and even more preferably about 0.05% to about 1.5% by weight solids, based upon the total weight of the composition taken as 100% by weight.

### 3. Optional Ingredients

The inventive compositions may also contain a number of optional ingredients, such as those selected from the group consisting of crosslinkers, surfactants, acids, acid catalysts, bases, base catalysts, polymers, catalysts, additives, and mixtures thereof.

For example, in embodiments a crosslinker can be included, with preferred crosslinkers being selected from the group consisting of aminoplasts (e.g., those sold under the name Powderlink® or Cymel® 1170 or Cymel® 303), epoxies (e.g., those sold under the name Araldite® MY720 tetra functional epoxy resin from Huntsman Advanced Materials), and mixtures thereof. When used, the crosslinker is preferably present in the composition at a level of about 5% to about 50% by weight, and preferably about 15% to about 35% by weight, based upon the total weight of the solids in the composition taken as 100% by weight.

In other embodiments, the underlayer composition is substantially free of any crosslinkers. That is, the underlayer composition will comprise less than about 0.001% by weight crosslinker, and preferably about 0% by weight crosslinker, based upon the total weight of the solids in the composition taken as 100% by weight.

In some embodiments, a catalyst (e.g., for crosslinking) is used. Preferred catalysts include, but are not limited to, those selected from the group consisting of 5-sulfosalycilic acid, TAG-2689, CXC-1821, sulfonic acids (e.g., p-toluenesulfonic acid, 5-sulfosalicylic acid), sulfonates (e.g., pyridinium p-toluenesulfonate, pyridinium trifluoromethanesulfonate, pyridinium 3-nitrobenzensulfonate), and combinations thereof. Other thermal acid generators can also be used. When utilized, the catalyst is typically present in the underlayer composition at a level of about 0.1% to about 10% by weight, and preferably about 1% to about 5% by weight, based upon the total weight of the solids in the composition taken as 100% by weight.

In other embodiments, the underlayer composition is substantially free of any catalysts. That is, the underlayer composition will comprise less than about 0.001% by weight catalyst, and preferably about 0% by weight catalyst, based upon the total weight of the solids in the composition taken as 100% by weight.

In some embodiments, a photoacid generator (PAG) is used. Preferably, the PAG is not attached to the polymer, oligomer, or monomer, but instead is simply mixed into the underlayer composition. Preferred PAGs include, but are not limited to, those selected from the group consisting of: onium salts (e.g., triphenyl sulfonium perfluorosulfonates such as TPS nonaflate, TPS triflate, and substituted forms thereof, such as tris(4-tert-butylphenyl)sulfonium perfluoro-1-butanesulfonate (an alkyl-substituted TPS nonaflate); oxime-sulfonates (e.g., those sold under the name CGI® by CIBA); triazines (e.g., TAZ-108® available from Midori Kagaku Company); and combinations thereof. When utilized, the PAG is typically included in the compositions at a level of about 0.001% to about 3% by weight, based upon the total weight of the solids in the composition taken as 100% by weight.

In other embodiments, the underlayer composition is substantially free of any acid generator such as a PAG. That is, the underlayer composition will comprise less than about 0.001% by weight acid generator, and preferably about 0% by weight acid generator, based upon the total weight of the solids in the composition taken as 100% by weight.

In some embodiments, an additive is used. Preferred additives include, but are not limited to, those selected from the group consisting of 1,1,1-tris(4-hydroxyphenyl)ethane (THPE), surfactants, and combinations thereof. When included, the additive is typically present in the composition at a level of about 0.001% to about 0.1% by weight, and preferably about 0.01% to about 0.05% by weight, based upon the total weight of the solids in the composition taken as 100% by weight.

In some embodiments, the composition consists essentially of, or even consists of, the pre-ionic compound dissolved or dispersed in the solvent system.

In other embodiments, the composition consists essentially of, or even consists of, the pre-ionic compound(s) and compound providing the third monomer dissolved or dispersed in the solvent system.

In other embodiments, the composition consists essentially of, or even consists of, the pre-ionic compound dissolved or dispersed in the solvent system, along with one, two, or three of a crosslinking agent, a catalyst (acid generator or otherwise), and/or an additive (THPE and/or surfactants).

In other embodiments, the composition consists essentially of, or even consists of, the pre-ionic compound and compound providing the third monomer dissolved or dispersed in the solvent system, along with one, two, or three of a crosslinking agent, a catalyst (acid generator or otherwise), and/or an additive (THPE and/or surfactants).

In one embodiment, dose-reducing molecules may be utilized selected from the group comprising imidazole, p-tolylsulfonic acid (p-TSA), acetic acid, iodoethane, iodomethane, imidazole diiodooctane, 1,8-diiodooctane, 1,5-diiodopentane, triphenylamine, 3,5-diiodosalicylic acid (DISA), 5-tris(oxiranylmethyl)-1,3,5-triazine2,4,6(1H,3H,5H)-trione (TEPIC), 1,4-diazabicyclooctane (DABCO), 2-methylimidazole, benzimidazole, 1-vinylimidazole, pyridinium p-toluene sulfonate (PpTS), 3-(8-iodooctyl)-3-imidazolium iodide, or combinations thereof.

Mixing the above ingredients together in the solvent system forms the underlayer composition. Furthermore, any optional ingredients (e.g., surfactants) are also dispersed in the solvent system at the same time.

### B. Ionic Compound Addition

In embodiments where an ionic compound (salt) is utilized, suitable compositions generally comprise one or more components dispersed or dissolved in a solvent system.

### 1. Salt

One such component is a salt, with both external salts and inner salts (i.e., zwitterions) being suitable for use herein. Salts for use in the present composition comprise a cationic portion that comprises a heterocyclic ring and/or a multi-heterocyclic ring, with that ring including at least one nitrogen ring member. In some embodiments, the ring comprises two nitrogen atoms as ring members. Preferably, a nitrogen atom of the ring carries the positive charge. Suitable rings can be aromatic or non-aromatic, and the ring can be a 5- or a 6-membered ring. In some embodiments, the cationic portion comprises a multicyclic structure, preferably comprised of two or more 5- and/or 6-membered rings. One or more nitrogen atoms of the ring can be substituted in some embodiments. Exemplary substitutions include substituted and unsubstituted alkyls (C₁ to about C₆, and preferably C₁ to about C₃), substituted and unsubstituted alkenyls (C₁ to about C₆, and preferably C₁ to about C₃), or combinations thereof. Examples of rings for use as the cationic portion of the salt include substituted and unsubstituted rings chosen from imidazoles (e.g., 1-vinylimidazole), pyridines, pyrimidines, pyrazines, pyridazines, purines, acridines, quinolines, isoquinolines, benzimidazoles, bi-pyridines, phenanthrenes, and/or combinations of the foregoing.

Suitable rings can include substitutions on one or more carbon atoms, with exemplary substitutions including those chosen from substituted and unsubstituted alkyls (preferably C₁ to about C₁₂, more preferably C₁ to about C₆, and even more preferably C₁ to about C₃), substituted and unsubstituted alkenyls (preferably C₁ to about C₁₂, more preferably C₁ to about C₆, and even more preferably C₁ to about C₃), or combinations thereof. In one or more embodiments, one or more carbon ring members are substituted with a vinyl group.

a. External Salts

In embodiments where the salt is an external salt, the cationic portion of the salt structure described above further comprises a portion or moiety according to Structure (I), a haloalkyl group, or combinations thereof.

Structure (I) comprises

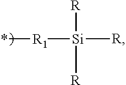

wherein:
each R is individually chosen (i.e., they can be the same or different) from substituted and unsubstituted alkyls (preferably C₁ to about C₁₀, more preferably C₁ to about C₆, and even more preferably C₁ to about C₃), substituted and unsubstituted alkoxys (preferably C₁ to about C₁₀, more preferably C₁ to about C₆, and even more preferably C₁ to about C₃), —OH, or combinations thereof;
R₁ is chosen from substituted and unsubstituted alkyls (preferably C₁ to about C₁₀, more preferably C₁ to about C₆, and even more preferably C₁ to about C₃), substituted and unsubstituted alkoxys (preferably C₁ to about C₁₀, more preferably C₁ to about C₆, and even more preferably C₁ to about C₃) or combinations thereof; and
“*” designates the location of the bond to the rest of the salt compound.
   In preferred embodiments, R₁ is bonded to a nitrogen atom on the previously described ring of the salt, and preferably to a nitrogen atom carrying a positive charge. In the same or different embodiments, it is preferred that R₁ is chosen from substituted and unsubstituted alkyls (preferably C₁ to about C₁₀, more preferably C₁ to about C₆, and even more preferably C₁ to about C₃).

In some embodiments, when the cationic portion comprises

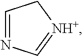

the anionic portion is not

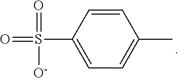

In some embodiments, the salt is not triphenylsulfonium nitrate.

Suitable haloalkyl groups comprise a halogen such as those chosen from iodine, fluorine, chlorine, bromine, or combinations thereof. The alkyl portion of the haloalkyl is chosen from substituted and unsubstituted alkyls (preferably C₂ to about C₁₄, more preferably C₂ to about C₁₀, and even more preferably C₂ to about C₅). In preferred embodiments, the alkyl of the haloalkyl is bonded to a nitrogen atom on the previously described ring of the salt, and preferably to a nitrogen atom carrying a positive charge.

In embodiments where the salt is an external salt, the anionic portion of the salt comprises an anion chosen from halogen anions (e.g., iodide, fluoride, chloride, bromide), hexafluorophosphate, tetrafluoroborate, tetrakis(pentafluorophenyl)borate, diiodooctane, dioodopentane, or combinations thereof.

Examples of external salts include one or more of

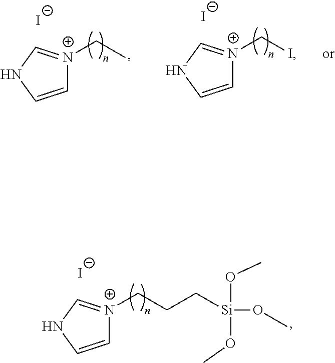

where n is 1 to 12, and more preferably 2 to 12.
   b. Inner Salt

In embodiments where the salt is an inner salt, the anionic portion of the salt comprises a moiety chosen from alkyl sulfonates, alkyl phosphates, or combinations thereof. Suitable alkyl sulfonates have the structure

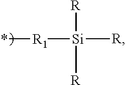

where R₂ is chosen from substituted and unsubstituted alkyls (preferably C₁ to about C₁₂, more preferably C₃ to about C₁₀, and even more preferably C₃ to about C), and “*” designates the location of the bond to the cationic portion of the inner salt. In preferred embodiments, R₂ is bonded to a nitrogen atom on the previously described ring of the cationic portion of the salt, and preferably to a nitrogen atom carrying a positive charge.

Examples of inner salts include

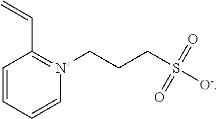

2. Polymeric, Oligomeric, and/or Monomeric Compound

In addition to a salt, the composition preferably comprises a compound (one or more monomers, oligomers, and/or polymers) dispersed or dissolved in the solvent system. In some embodiments, the compound is or includes a silicon-containing monomer, oligomer, and/or polymer. Examples of suitable monomeric compounds include those chosen from the following, along with oligomers and/or polymers (including copolymers) thereof: tetraethoxysilane, methyltrimethoxysilane, isobutyltrimethoxysilane, phenyltrimethoxysilane, 2-(3,4-epoxycyclohexyl)-ethyltrimethoxysilane, 3-triethoxysilylpropylsuccinic anhydride, 3-iodopropyltrimethoxysilane, triethoxy-3-(2-imidazolin-1-yl)propylsilane (IMIDTEOS), dimethylaminopropyltrimethoxysilane (DMAPTMS), glycidylPOSS, (3-glycidyloxypropyl)trimethoxysilane (glyTMS), 2-(3,4-epoxycyclohexyl)ethyltrimethoxysilane (ECHTMS), trihydroxysilylethylphenylsulphonic acid (THSPSA), 5,6-epoxyhexyltriethoxysilane (EPOTEOS), triethoxysilylpropylethylcarbamate (TEOSPEC), n-(3-triethoxysilylpropyl)-4-hydroxybutyramide (HATEOS), triethoxysilylpropylsuccinicanhydride (TEOSPSA), 2-(carbomethoxy)ethyltrimethoxysilane (CarboTMS), vinyltrimethoxysilane (VTMS), 3-(trihydroxysilyl)-1-propanesulfonic acid (THSSA), (3-glycidoxypropyl)methyldiethoxysilane (GlyDEOS), methacrylamidopropyltriethoxysilane, aminopropyltriethoxysilane, 3-aminopropyl(diethoxy)methylsilane (APDEOS), or combinations thereof.

Suitable polymers also include carbon-rich polymers, such as those chosen from polystyrene, functionalized polystyrene derivatives (e.g., poly(4-methylstyrene), poly(vinyl naphthalene)), polysulfones, polyethersulfones, poly(ether ether ketone), polycarbonates, epoxies, novolacs, polyimides, or combinations thereof.

In some embodiments, suitable polymers and/or oligomers for use as the compound comprise monomers chosen from phenolic compounds, styrene, styrene-containing compounds, glycidyl-containing compounds, 2-hydroxyethyl methacrylate, hydroxypropyl methacrylate, hydroxybutylacrylate, silanes, siloxanes, or combinations thereof.

In the same or different embodiments, the compound can be a monomeric compound, such as those chosen from phenolic compounds, styrene, styrene-containing compounds, glycidyl-containing compounds, 2-hydroxyethyl methacrylate, hydroxypropyl methacrylate, hydroxybutylacrylate, silanes (e.g., 2-(3,4-epoxycyclohexyl)ethyltrimethoxysilane), or combinations thereof.

In embodiments where the compound is a polymer, that polymer can be purchased commercially or formed according to known polymerization methods (e.g., free radical polymerization). Additionally, the weight-average molecular weight (Mw) range (as measured by gel permeation chromatography) of the polymer is typically about 500 g/mol to about 150,000 g/mol, preferably about 1,000 g/mol to about 80,000 g/mol, and more preferably from about 2,000 g/mol to about 25,000 g/mol.

In one or more embodiments, the compound (total polymeric, oligomeric, and monomeric) will be present in the composition at levels of about 0.05% by weight to about 20% by weight, preferably about 0.05% to about 10%, and more preferably about 0.1% by weight to about 5% by weight, based upon the total weight of the composition taken as 100% by weight.

In the same or other embodiments, the compound (total polymeric, oligomeric, and monomeric) will be present in the composition at levels of about 30% by weight to about 99% by weight, preferably about 40% by weight to about 98% by weight, and more preferably about 50% by weight to about 95% by weight, based upon the total weight of the solids in the composition taken as 100% by weight.

### 3. Catalyst

In some embodiments, a crosslinking catalyst is utilized. Preferred catalysts include those chosen from 5-sulfosalycilic acid, thermal acid generator such as quaternary ammonium blocked triflic acid (such as that sold under the name K-Pure TAG2689), sulfonic acids (e.g., p-toluenesulfonic acid, styrene sulfonic acid), sulfonates (e.g., pyridinium p-toluenesulfonate, pyridinium trifluoromethanesulfonate, pyridinium 3-nitrobenzensulfonate), ethyltriphenylphosphonium bromide, benzyltriethylammonium chloride, or mixtures thereof. Typical catalyst levels in the composition are about 0.01% to about 0.05% by weight, and preferably about 0.01% to about 0.02% by weight, based upon the total weight of the solids in the composition taken as 100% by weight. 4. Solvent System

Exemplary solvent systems include one or more solvents chosen from propylene glycol methyl ether acetate (PGMEA), propylene glycol methyl ether (PGME), propylene glycol ethyl ether (PGEE), propylene glycol n-propyl ether (PnP), ethyl lactate, cyclopentanone, cyclohexanone, gamma-butyrolactone (GBL), methyl isobutyl carbinol, 3-methyl-1,5-pentanediol, 1,2-propylene glycol, 1,3-propylene glycol, ethylene glycol, water, or mixtures thereof.

The solvent system is preferably utilized at a level of about 20% to about 99.99% by weight, more preferably about 80% to 99.9%, and even more preferably about 90% to about 99.9% by weight, based upon the total weight of the composition taken as 100% by weight. The compositions used to form the underlayer preferably comprise a solids content of about 0.01% to about 20% by weight solids, more preferably about 0.01% to about 10% by weight solids, and even more preferably about 0.05% to about 1.5% by weight solids, based upon the total weight of the composition taken as 100% by weight.

### 5. Composition Preparation

The salt, any compound (polymeric, oligomeric, and/or monomeric), catalyst, and any optional ingredients (e.g., surfactants) are mixed together in the solvent system under ambient conditions until a dispersion or solution is formed.

The amount of salt included in the composition on a solids basis is typically about 5% or more, preferably about 5% to about 75% by weight, more preferably about 10% to about 55% by weight, and even more preferably about 30% to about 55% by weight, based on the total solids in the composition taken as 100% by weight.

In one or more embodiments, the amount of salt included based on the total weight of the polymeric, oligomeric, and monomeric compound present is typically about 0.1% to about 20% by weight, preferably about 1% to about 15% by weight, and more preferably about 1% to about 10% by weight. In other embodiments, the amount of salt included is based on the total weight of the polymeric, oligomeric, and monomeric compound present is typically about 25% to about 75% by weight, preferably about 35% to about 65% by weight, and more preferably about 40% to about 60% by weight.

In one or more embodiments, the composition comprises little to no triphenylsulfonium nitrate. In such embodiments, the composition comprises less than about 0.005% by weight triphenylsulfonium nitrate, preferably less than about 0.001% by weight triphenylsulfonium nitrate, and more preferably about 0% by weight triphenylsulfonium nitrate, based upon the total weight of the solids in the composition taken as 100% by weight.

In some embodiments, the composition consists essentially of, or even consists of, the salt, compound (polymeric, oligomeric, and/or monomeric), and catalyst dissolved or dispersed in the solvent system.

### C. Ionic Moiety Addition

In embodiments, where an ionic moiety is utilized, suitable compositions generally comprise one or more components dispersed or dissolved in a solvent system. Broadly, the component comprises a polymer, oligomer, and/or monomer comprising a salt. A salt (through its cationic portion) can be bonded to the polymer, oligomer, and/or monomer, typically as a functional group or part of a side chain in the case of a polymer and/or oligomer. Additionally or alternatively, the salt can be part of the polymer and/or oligomer backbone.

Examples of suitable monomeric compounds include those chosen from the following, along with oligomers and/or polymers (including copolymers and/or blends) thereof: tetraethoxysilane, methyltrimethoxysilane, isobutyltrimethoxysilane, phenyltrimethoxysilane, 2-(3,4-epoxycyclohexyl)-ethyltrimethoxysilane, 3-triethoxysilylpropylsuccinic anhydride, 3-iodopropyltrimethoxysilane, triethoxy-3-(2-imidazolin-1-yl)propylsilane (IMIDTEOS), dimethylaminopropyltrimethoxysilane (DMAPTMS), glycidylPOSS, (3-glycidyloxypropyl)trimethoxysilane (glyTMS), 2-(3,4-epoxycyclohexyl)ethyltrimethoxysilane (ECHTMS), triphydroxysilylethylphenylsulphonic acid (THSPSA), 5,6-epoxyhexyltriethoxysilane (EPOTEOS), triethoxysilylpropylethylcarbamate (TEOSPEC), n-(3-triethoxysilylpropyl)-4-hydroxybutyramide (HATEOS), triethoxysilylpropylsuccinicanhydride (TEOSPSA), 2-(carbomethoxy)ethyltrimethoxysilane (CarboTMS), vinyl trimethoxysilane (VTMS), 3-(trihydroxysilyl)-1-propanesulfonic acid (THSSA), (3-glycidoxypropyl)methyldiethoxysilane (GlyDEOS), methacrylamidopropyltriethoxysilane, aminopropyltriethoxysilane, 3-aminopropyl(diethoxy)methylsilane (APDEOS), or combinations thereof.

In some embodiments, suitable polymers also include carbon-rich polymers, such as those chosen from polystyrene, functionalized polystyrene derivatives (e.g., poly(4-methylstyrene), poly(vinyl naphthalene)), polysulfones, polyethersulfones, poly(ether ether ketone), polycarbonates, epoxies, novolacs, polyimides, 1-(3-sulfopropyl)-2-vinylpyridinium hydroxide, or combinations thereof.

In some embodiments, suitable polymers and/or oligomers for use as the component comprise monomers chosen from phenolic compounds, styrene, styrene-containing compounds, glycidyl-containing compounds, 2-hydroxyethyl methacrylate, hydroxypropyl methacrylate, hydroxybutylacrylate, silanes, siloxanes, or combinations thereof.

In the same or different embodiments, the component can be a monomeric compound, such as those chosen from phenolic compounds, styrene, styrene-containing compounds, glycidyl-containing compounds, 2-hydroxyethyl methacrylate, hydroxypropyl methacrylate, hydroxybutylacrylate, silanes (e.g., 2-(3,4-epoxycyclohexyl)ethyltrimethoxysilane), or combinations thereof.

Suitable cationic moieties bonded with the polymer, oligomer, and/or monomer such as those listed above comprise a heterocyclic ring and/or a multi-heterocyclic ring, with that ring including at least one nitrogen ring member. In some embodiments, the ring comprises two nitrogen atoms as ring members. Preferably, a nitrogen atom of the ring carries the positive charge. Suitable rings can be aromatic or non-aromatic, and the ring can be a 5- or a 6-membered ring. In some embodiments, the cationic moiety comprises a multicyclic structure, preferably comprised of two or more 5- and/or 6-membered rings. One or more nitrogen atoms of the ring can be substituted in some embodiments. Exemplary substitutions include substituted and unsubstituted alkyls (C₁ to about C₆, and preferably C₁ to about C₃), substituted and unsubstituted alkenyls (C₁ to about C₆, and preferably C₁ to about C₃), or combinations thereof. Examples of rings for use as the cationic portion of the salt include substituted and unsubstituted rings chosen from imidazoles (e.g., 1-vinylimidazole), pyridines, pyrimidines, pyrazines, pyridazines, purines, acridines, quinolines, isoquinolines, benzimidazoles, bi-pyridines, phenanthrenes, and/or combinations of the foregoing.

Suitable rings can include substitutions on one or more carbon atoms, with exemplary substitutions including those chosen from substituted and unsubstituted alkyls (preferably C₁ to about C₁₂, more preferably C₁ to about C₆, and even more preferably C₁ to about C₃), substituted and unsubstituted alkenyls (preferably C₁ to about C₁₂, more preferably C₁ to about C₆, and even more preferably C₁ to about C₃), or combinations thereof. In one or more embodiments, one or more carbon ring members are substituted with a vinyl group.

The anion from the salt will depend on the particular reactants, discussed in more detail below, but in some instances, the anion is chosen from halogen anions (e.g., iodide, fluoride, chloride, bromide), hexafluorophosphate, tetrafluoroborate, tetrakis(pentafluorophenyl)borate, or combinations thereof. In some embodiments, the salt bound to the polymer is an external salt. In other embodiments, the salt bound to the polymer is an inner salt, in which case the anion will be bonded to the cation on the polymer, oligomer, and/or monomer.

In the same or other embodiments, the anion comprises a moiety chosen from alkyl sulfonates, alkyl phosphates, or combinations thereof. Suitable alkyl sulfonates have the structure

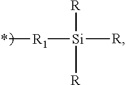

where R₂ is chosen from substituted and unsubstituted alkyls (preferably C₁ to about C₁₂, more preferably C₃ to about C₁₀, and even more preferably C₃ to about C₆), and “*” designates the location of the bond to the cationic portion of the inner salt. In preferred embodiments, R₂ is bonded to a nitrogen atom on the previously described ring of the cationic portion of the salt, and preferably to a nitrogen atom carrying a positive charge.

In some embodiments, when the ring of the cation is

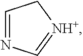

the anion is not

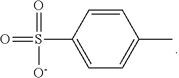

In some embodiments, the salt from which the cation and anion are derived is not triphenylsulfonium nitrate.

A suitable method of forming the above-described components involves an alkylation-type reaction, preferably using a halide. In some instances, the halide is part of the monomer, and that monomer can be used in the compositions and/or that monomer can be used to form an oligomer and/or polymer in oligomeric or polymeric embodiments. Examples of such halide-containing monomers include 3-iodopropyltrimethoxysilane, 3-dimethylaminopropyltrimethoxysilane and triethoxy-3-(2-imidazolin-1-yl)propylsilane (IMIDTEOS), or combinations thereof.

When the halide is part of the monomer, the component can be formed by reacting a compound comprising a ring structure as described above with the halide-containing monomer, oligomer, and/or polymer following conventional methods so as to form the component comprising a cationic moiety. Examples of suitable such ring-containing compounds include those chosen from imidazoles (e.g., 1-vinylimidazole, 1-methylimidazole, 2-methylimidazole, benzimidazole), pyridines, pyrimidines, purines, pyrazolines, phenanthrenes, 1,4-diazabicyclooctane (DABCO), or combinations thereof.

In some embodiments, the monomer, oligomer, and/or polymer may already contain a ring as described above. In these instances, it is preferred to carry out the alkylation-type reaction with a halide, such as an alkyl halide. Suitable halides are chosen from iodine, fluorine, chlorine, bromine, or combinations thereof. Suitable alkyl halides include C₁ to about C₁₄, preferably C₂ to about C₁₀, and more preferably C₂ to about C₈ alkyl halides. Preferred alkyl halides are chosen from iodoethane, iodomethane, 1,8-diiodooctane, 1,5-diiodopentane, or combinations thereof.

In some embodiments, it is desirable to carry out the alkylation-type reaction during oligomerization and/or polymerization, which can be carried out according to known oligomerization and/or polymerization methods (e.g., free radical polymerization). In some instances, polymer can be purchased commercially.

In embodiments where an oligomer or polymer is utilized, the weight-average molecular weight (Mw) range (as measured by gel permeation chromatography) is typically about 500 g/mol to about 150,000 g/mol, preferably about 1,000 g/mol to about 80,000 g/mol, and more preferably from about 2,000 g/mol to about 25,000 g/mol.

Additionally or alternatively, about 50% or more, preferably about 75% or more, more preferably about 90% or more, and even more preferably about 100% of the monomers of the oligomer or polymer will comprise a cationic moiety as described herein. In one or more embodiments, the ratio of cation to anion will be about 0.9:1.1, preferably about 0.95:1.05, and more preferably about 1:1.

In some embodiments where an oligomer or polymer is utilized, the component is a homo-oligomer or homopolymer.

In one or more embodiments, the component (total polymeric, oligomeric, and monomeric) will be present in the composition at levels of about 0.05% by weight to about 20% by weight, preferably about 0.05% to about 10%, and more preferably about 0.1% by weight to about 5% by weight, based upon the total weight of the composition taken as 100% by weight.

Regardless of the particular component (polymeric, oligomeric, and/or monomeric) selected, the underlayer compositions for use herein are formed by mixing the component in a solvent system under ambient conditions until a dispersion or solution is formed. The component will typically be present in the underlayer composition at levels of about 30% by weight to about 99% by weight, preferably about 40% by weight to about 98% by weight, and more preferably about 50% by weight to about 95% by weight, based upon the total weight of the solids in the composition taken as 100% by weight.

Exemplary solvent systems include one or more solvents chosen from propylene glycol methyl ether acetate (PGMEA), propylene glycol methyl ether (PGME), propylene glycol ethyl ether (PGEE), propylene glycol n-propyl ether (PnP), ethyl lactate, cyclopentanone, cyclohexanone, gamma-butyrolactone (GBL), methyl isobutyl carbinol, 3-methyl-1,5-pentanediol, 1,2-propylene glycol, 1,3-propylene glycol, ethylene glycol, water, or mixtures thereof. Preferably, the solvent system has a boiling point of about 700 to about 200° C., and more preferably about 1000 to about 150° C.

In some embodiments, the solvent system is preferably utilized at a level of about 98% to about 99.99% by weight, more preferably about 99% to 99.9%, and even more preferably about 99.3% to about 99.8% by weight, based upon the total weight of the composition taken as 100% by weight. In other embodiments, the solvent system is utilized at a level of about 20% to about 99.99% by weight, preferably about 80% to 99.9%, and more preferably about 90% to about 99.9% by weight, based upon the total weight of the composition taken as 100% by weight.

In some embodiment, the compositions used to form the underlayer preferably comprise a solids content of about 0.1% to about 2% by weight solids, more preferably about 0.1% to about 1% by weight solids, and even more preferably about 0.1% to about 0.5% by weight solids, based upon the total weight of the composition taken as 100% by weight. In other embodiments, the compositions used to form the underlayer preferably comprise a solids content of about 0.01% to about 20% by weight solids, preferably about 0.01% to about 10% by weight solids, and more preferably about 0.05% to about 1.5% by weight solids, based upon the total weight of the composition taken as 100% by weight.

A number of optional ingredients could be included in the underlayer composition, and those ingredients would simply be mixed with the solvent system at the same time as the component. For example, in embodiments a crosslinker can be included, with preferred crosslinkers being selected from the group consisting of aminoplasts (e.g., those sold under the name Powderlink® or Cymel® 1170 or Cymel® 303), epoxies (e.g., those sold under the name Araldite® MY720 tetra functional epoxy resin from Huntsman Advanced Materials), and mixtures thereof. When used, the crosslinker is preferably present in the composition at a level of about 5% to about 50% by weight, and preferably about 15% to about 35% by weight, based upon the total weight of the solids in the composition taken as 100% by weight.

In other embodiments, the underlayer composition is substantially free of any crosslinkers. That is, the underlayer composition will comprise less than about 0.001% by weight crosslinker, and preferably about 0% by weight crosslinker, based upon the total weight of the solids in the composition taken as 100% by weight.

In some embodiments, a catalyst (e.g., for crosslinking) is used. Preferred catalysts include, but are not limited to, those selected from the group consisting of 5-sulfosalycilic acid, TAG-2689, CXC-1821, sulfonic acids (e.g., p-toluenesulfonic acid, 5-sulfosalicylic acid), sulfonates (e.g., pyridinium p-toluenesulfonate, pyridinium trifluoromethanesulfonate, pyridinium 3-nitrobenzensulfonate), and combinations thereof. Other thermal acid generators can also be used. When utilized, the catalyst is typically present in the underlayer composition at a level of about 0.1% to about 10% by weight, and preferably about 1% to about 5% by weight, based upon the total weight of the solids in the composition taken as 100% by weight.

In other embodiments, the underlayer composition is substantially free of any catalysts. That is, the underlayer composition will comprise less than about 0.001% by weight catalyst, and preferably about 0% by weight catalyst, based upon the total weight of the solids in the composition taken as 100% by weight.

In some embodiments, a photoacid generator (PAG) is used. Preferably, the PAG is not attached to the polymer, oligomer, or monomer, but instead is simply mixed into the underlayer composition. Preferred PAGs include, but are not limited to, those selected from the group consisting of: onium salts (e.g., triphenyl sulfonium perfluorosulfonates such as TPS nonaflate, TPS triflate, and substituted forms thereof, such as tris(4-tert-butylphenyl)sulfonium perfluoro-1-butanesulfonate (an alkyl-substituted TPS nonaflate); oxime-sulfonates (e.g., those sold under the name CGI® by CIBA); triazines (e.g., TAZ-108® available from Midori Kagaku Company); and combinations thereof. When utilized, the PAG is typically included in the compositions at a level of about 0.001% to about 3% by weight, based upon the total weight of the solids in the composition taken as 100% by weight.

In other embodiments, the underlayer composition is substantially free of any acid generator such as a PAG. That is, the underlayer composition will comprise less than about 0.001% by weight acid generator, and preferably about 0% by weight acid generator, based upon the total weight of the solids in the composition taken as 100% by weight.

In some embodiments, an additive is used. Preferably, the additive is simply mixed into the underlayer composition. Preferred additives include, but are not limited to, those selected from the group consisting of 1,1,1-tris(4-hydroxyphenyl)ethane (THPE), surfactants, and combinations thereof. When included, the additive is typically present in the composition at a level of about 0.001% to about 0.1% by weight, and preferably about 0.01% to about 0.05% by weight, based upon the total weight of the solids in the composition taken as 100% by weight.

In some embodiments, the composition consists essentially of, or even consists of, the component (polymeric, oligomeric, and/or monomeric), dissolved or dispersed in the solvent system.

In other embodiments, the composition consists essentially of, or even consists of, the component (polymeric, oligomeric, and/or monomeric), dissolved or dispersed in the solvent system, along with one, two, or three of a crosslinking agent, a catalyst (acid generator or otherwise), and/or an additive (THPE and/or surfactants).

### Methods of Using the Compositions to Form EUV Underlayer

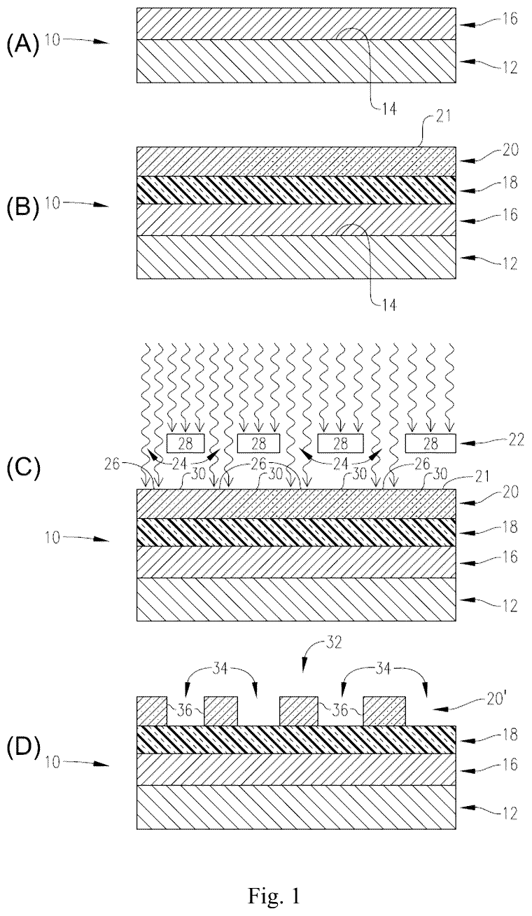

Referring to FIG. 1(A), a stack 10 is schematically depicted. Stack 10 comprises a substrate 12 having a surface 14 and optional intermediate layer(s) 16.

Substrate 12 comprises a microelectronic substrate, which is typically a semiconductor substrate. Exemplary substrates 12 comprise silicon, SiGe, SiO₂, Si₃N₄, SiON, SiCO:H (such as that sold under the name Black Diamond, by SVM, Santa Clara, CA, US), tetramethyl silate and tetramethyl-cyclotetrasiloxane combinations (such as that sold under the name CORAL), aluminum, tungsten, tungsten silicide, gallium arsenide, germanium, tantalum, tantalum nitride, Ti₃N₄, hafnium, HfO₂, ruthenium, indium phosphide, glass, or combinations of the foregoing. Surface 14 of substrate 12 can be planar, or it can include topographic features (e.g., via holes, trenches, contact holes, raised features, lines, etc.). As used herein, “topography” refers to the height or depth of a structure in or on substrate surface 14. In FIG. 1(A) the surface 14 is illustrated as having a substantially planar topography, but the topography could include non-planar topographies, such as those including lines, trenches, holes, pillars, etc.

FIG. 1 shows a single intermediate layer 16 for illustration purposes, however, the stack 10 can include multiple intermediate layers or no intermediate layers. In some embodiments, a suitable intermediate layer 16 includes a primer layer, which can include a separate and distinct layer or a layer that is more appropriately characterized as a modification of substrate surface 14. Preferred primers include hexamethyldisilizane (“HMDS”). A primer can be formed, for example, by exposing the substrate 12 to a vapor of a primer composition in a sealed chamber while heating at about 150° C. for about 90 seconds.

Another suitable intermediate layer 16 comprises a carbon-rich layer that may be formed on substrate surface 14, or on any other intermediate layer that may be present (e.g., the primed layer or modified surface as discussed above). Carbon-rich layers include, but are not limited to, spin-on carbon (SOC) layers, amorphous carbon layers, and carbon planarizing layers. Exemplary carbon-rich layers are generally formed from a carbon-rich composition comprising a polymer dissolved or dispersed in a solvent(s), along with one or more optional ingredients, including those chosen from acid quenchers, base quenchers, catalysts, crosslinking agents, surface modification additives, or mixtures thereof. Preferred carbon-rich compositions will be capable of being formed into relatively thick layers and thus typically have a solids content of about 0.1% to about 70% by weight, more preferably about 5% to about 40% by weight, and even more preferably about 10% to about 30% by weight, based upon the total weight of the carbon-rich composition taken as 100% by weight. The term “carbon-rich” refers to compositions and/or layers comprising greater than about 50% by weight carbon, preferably greater than about 70% by weight carbon, more preferably from about 75% to about 95% by weight carbon, and even more preferably about 75% to about 90% by weight carbon, based upon the total solids in the composition or layer taken as 100% by weight.

The carbon-rich layer can be formed by any known application method, with one preferred method being spin-coating at speeds of about 1,000 to about 5,000 rpm, and preferably about 1,250 to about 1,750 rpm, for a time period of about 30 to about 120 seconds, preferably about 45 to about 75 seconds. After the carbon-rich composition is applied, it is preferably heated to a temperature of about 100° C. to about 400° C., and more preferably about 160° C. to about 350° C., for a time period of about 30 seconds to about 120 seconds, and preferably about 45 seconds to about 60 seconds, to evaporate solvents. The average thickness of the carbon-rich layer after baking is typically about 5 nm to about 1,000 nm, preferably about 5 nm to about 200 nm, more preferably about 5 nm to about 120 nm, even more preferably about 5 nm to about 100 nm, and most preferably about 10 nm to about 60 nm. As used herein, “average thickness” is determined using an ellipsometer and taking the average of five measurements at five different locations. The carbon-rich layer preferably has an etch rate in oxygen-rich plasma that is at least about 5 time faster than the etch rate of the resist in the same plasma. The carbon-rich layer may also be formed by other conventional application methods, including chemical vapor deposition (“CVD”), plasma-enhanced chemical vapor deposition (“PECVD”), atomic layer deposition (“ALD”), or plasma-enhanced atomic layer deposition (“PEALD”). Suitable carbon-rich layers are commercially available from Brewer Science, Inc. (Rolla, MO) under the name OptiStack® SOC450 material.

An optional hardmask layer may be applied adjacent to the carbon-rich material, to the substrate surface 14, or any intermediate layers on the substrate surface 14. In some instances, hardmasks may be unnecessary for current state-of-the-art lithography stacks due to the etch resistance provided by other materials. The hardmask layer can be formed by any known application method, such as CVD or PECVD. Another preferred method is spin-coating at speeds of about 1,000 to about 5,000 rpm, and preferably about 1,250 to about 1,750 rpm, for a time period of about 30 to about 120 seconds, and preferably about 45 to about 75 seconds.

Suitable hardmask layers are preferably high-silicon-content materials such as those selected from the group consisting of silanes, siloxanes, silsesquioxanes, silicon oxynitride, silicon nitride, polysilicon, amorphous silicon, or mixtures thereof, or any layer with a high etch bias relative to the underlying layers. Suitable hardmask layers generally compromise a polymer dissolved or dispersed in a solvent system, along with one or more of the following optional ingredients: surfactants, acid or base catalysts, and crosslinkers.

Preferred compositions for forming a hardmask layer preferably have a solids content of about 0.1% to about 70% by weight, more preferably about 0.5% to about 10% by weight, even more preferably about 0.5% to about 2% by weight, and most preferably about 0.5% to about 1% by weight, based upon the total weight of the hardmask composition taken as 100% by weight. After the hardmask is applied, it is preferably heated at a temperature of about 100° C. to about 300° C., and more preferably about 150° C. to about 250° C., for a time period of about 30 seconds to about 120 seconds, and preferably about 45 seconds to about 60 seconds, to evaporate solvents. The average thickness of the hardmask layer after baking is preferably about 5 nm to about 5,000 nm, more preferably about 5 nm to about 1,000 nm, even more preferably about 5 nm to about 100 nm, and most preferably about 10 nm to about 30 nm. The hardmask layer preferably has an etch rate that is about 0.75 times or higher than that of the photoresist in a fluorine-rich plasma atmosphere. Additionally or alternatively, the hardmask layer etch rate is preferably about 20% or less (i.e., five times slower) than that of the carbon-rich layer in an oxygen-rich plasma etch atmosphere.

Commercial hardmask layers can be used. For example, materials commercially available from Brewer Science, Inc. (Rolla, MO) under the tradenames OptiStack® HM710 and OptiStack® HM825 can be used to form suitable hardmasks. Other suitable hardmask layers contain a copolymer of monomers selected from the group containing phenethyltrimethoxysilane, 2-(carbomethoxy)ethyltrimethoxysilane, tetraethoxysilane, methyltrimethoxysilane, phenyltrimethoxysilane, methyltrimethoxysilane, ethyltrimethoxysilane, (3-glycidyoxypropyl)triethoxysilane, 2-(3,4-epoxycyclohexyl)ethyltrimethyoxysilane, or combinations thereof.

Especially preferred silicon hardmasks have a lower carbon content, preferably less than about 30% carbon, more preferably less than about 25% carbon, and even more preferably less than about 20% carbon, all by weight on a solids basis. The silicon hardmask preferably has a higher silicon content, preferably at least about 25% silicon, more preferably at least about 30% silicon, and even more preferably at least about 40% silicon, all by weight on a solids basis.

Regardless of whether zero, one, two, or more intermediate layers are included in stack 10, an underlayer composition as previously described is used to form an underlayer 18 (FIG. 1(B)). Underlayer 18 can be formed directly on the substrate surface 14 if no intermediate layer is utilized (not shown), on the intermediate layer 16 if only one intermediate layer is utilized (as in FIG. 1B, e.g., a carbon-rich layer), or on the intermediate layer that is positioned furthest from substrate surface 14 (i.e., the uppermost intermediate layer, which is preferably a hardmask layer) in embodiments where multiple intermediate layers are included (not shown).

One preferred application method involves spin-coating the underlayer composition at speeds of about 1,000 rpm to about 5,000 rpm, and preferably about 1,250 rpm to about 1,750 rpm, for a time period of about 30 seconds to about 120 seconds, and preferably about 45 seconds to about 75 seconds. After the underlayer composition is applied to form underlayer 18, underlayer 18 is preferably heated at a temperature sufficiently high to evaporate substantially all (about 95% or more) and preferably all (about 100%) of the solvent present in underlayer 18. Suitable baking conditions typically involve temperatures of about 100° C. to about 300° C., and more preferably about 150° C. to about 250° C., for about 30 seconds to about 120 seconds, and preferably about 45 seconds to about 60 seconds.

During baking in embodiments using a pre-ionic compound, the pre-ionic compound will generate an ionic compound, an ionic moiety, or both. In some embodiments, this is accomplished during the crosslinking reaction, which forms a (crosslinked) polymer network. For example, an organic salt can be formed by the nitrogen of the tertiary amine attacking and/or reacting with the epoxide during baking. An example of this reaction is shown below.

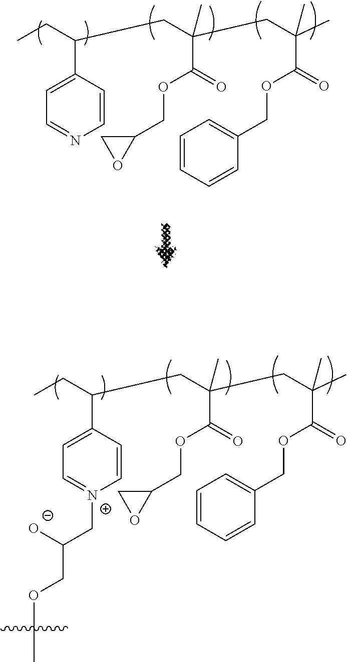

In other embodiments, the nitrogen of the tertiary amine reacts with the alkyl halide, which functions as a leaving group, thus forming a crosslinked underlayer 18. An example of this reaction is shown below.

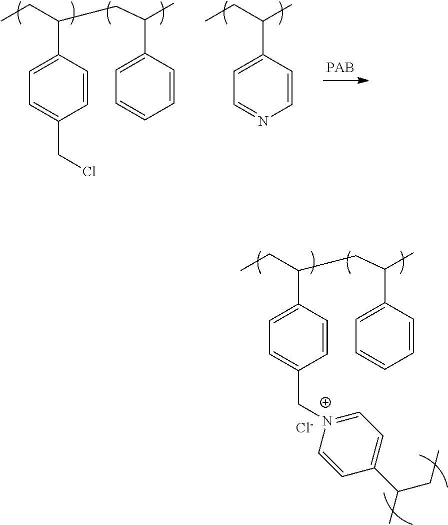

In embodiments where an ionic compound is utilized in the underlayer composition, the previously described polymer, oligomer, and/or monomer in the underlayer composition will crosslink during baking, thus forming a crosslinked polymer, oligomer, and/or monomer network with the anionic and cationic components from the salt being dispersed or distributed within that crosslinked network within formed underlayer 18, preferably in a substantially homogeneous manner.

In embodiments where an ionic moiety is utilized in the underlayer composition, the previously described polymer, oligomer, and/or monomer with cationic moiety of the underlayer composition will crosslink during baking, thus forming a crosslinked polymer, oligomer, and/or monomer network, and the anion from the salt will preferably be dispersed, distributed, and/or interspersed within that crosslinked network within formed underlayer 18, preferably in a substantially homogeneous manner.

In some embodiments where an ionic moiety is utilized, some or all of the polymer, oligomer, and/or monomer with cationic moiety will bond with the layer immediately below underlayer 18, with the anion from the salt preferably being dispersed, distributed, and/or interspersed within or among the polymer, oligomer, and/or monomer with cationic moiety.

In even further embodiments where an ionic moiety is utilized, both crosslinking of the polymer, oligomer, and/or monomer with cationic moiety and bonding with the layer immediately below underlayer 18 will take place, again with the anion from the salt being dispersed, distributed, and/or interspersed within or among the crosslinked and/or uncrosslinked polymer, oligomer, and/or monomer with cationic moiety.

In some embodiments where an ionic moiety is utilized, the solvent is evaporated during baking as mentioned above, but the previously described polymer, oligomer, and/or monomer do not crosslink during baking. In these instances, the anion from the salt is dispersed or distributed within the (uncrosslinked) polymer, oligomer, and/or monomer within the formed underlayer 18, preferably in a substantially homogeneous manner.

The average thickness of the underlayer 18 after baking is less than about 20 nm, preferably about 1 nm to 20 nm, more preferably about 2 nm to about 15 nm, and even more preferably about 4 nm to about 10 nm. If the substrate surface includes topography, the underlayer is preferably applied at a thickness sufficient to substantially cover the substrate topography.

In some embodiments, the underlayer 18 has a low metal content. That is, the metal content is less than about 0.005% by weight, preferably less than about 0.001% by weight, and more preferably about 0% by weight, based upon the total weight of the underlayer 18 taken as 100% by weight. It is also preferred that the underlayer 18 is non-conducting.

It will be appreciated that the desired contact angle when a drop of water is placed on the underlayer 18 depends on the application. The surface contact angle of underlayer 18 can be determined by averaging 5 measurements taken in different spots using VCA-3000S Wafer System (AST Products, Billerica, MA) contact angle measurement tool, with water as the droplet solvent. In some embodiments, the contact angle of the underlayer 18 after baking is preferably about 500 to about 80°, and more preferably about 550 to about 65°.

It is preferred that the underlayer 18 is substantially non-developable using (i.e., substantially insoluble in) typical organic solvents such as ethyl lactate, propylene glycol methyl ether acetate, propylene glycol methyl ether, propylene glycol n-propyl ether, cyclohexanone, acetone, gamma butyrolactone, or mixtures thereof. Thus, when subjected to a stripping test, the formed underlayer 18 preferably has a percent stripping of less than about 5%, more preferably less than about 1%, and even more preferably about 0%.

The percent stripping can be determined by measuring the average contact angle and average thickness (each determined by averaging measurements taken at five different locations) of the underlayer 18 before the underlayer 18 is exposed to any developer solvents. These averaged measurements are the initial film contact angle and initial film thickness. Next, a solvent (e.g., ethyl lactate) is puddled onto the film for about 30 seconds, followed by spin drying at about 3,000 rpm for about 30 seconds to remove the solvent. The average contact angle and average thickness are each determined again by measuring at approximately the same five locations on the wafer as the locations used to determine the initial film contact angle and initial film thickness, and the averages of these measurements are the final film contact angle and the final film thickness, respectively.

The amount of stripping is the difference between the initial and final film thicknesses. The percent stripping is:

$$\% stripping = ( \frac{amount of stripping}{initial average film thickness} ) \times 100.$$

The underlayer 18 is preferably sufficiently crosslinked that % stripping is less than about 5%, more preferably less than about 1%, and even more preferably less than about 0%.

In one embodiment, solvent resistance to methyl isobutyl carbinol (MIBC) may be evaluated by stripping test by puddling ˜6 mL of solvent on the baked underlayer for 30 seconds followed by 30 seconds of spin-drying at 1500 rpm. Preferably, the MIBC strip will be from about −15% to about 5%, more preferably from about −10% to about 0%, where negative stripping values indicate swelling. Developer resistance may be evaluated via the developer stripping by puddling ˜6 mL of developer (Inpria Corporation) on the baked underlayer for 60 seconds followed by 60 seconds of spin-drying at 1500 rpm.

In addition to the strip test, there are additional indications of a high degree of crosslinking of the underlayer 18. Preferably, there are substantially no changes in the water contact angle after contact with solvent or developer, that is, the change in contact angle is preferably less than about 50, more preferably less than about 3°.

Another indicator of sufficient crosslinking is good thickness uniformity and a substantially uniform and defect-free surface as measured on a KLA SP5. Preferably, the underlayer 18 will have sublimation of less than about 200 ng, more preferably less than about 100 ng, and even more preferably less than about 50 ng when measured with a quartz crystal microbalance (QCM) when heated to about 205° C. for about 3 minutes. A well-crosslinked underlayer 18 will generally have a surface roughness (R1) as measured with atomic force microscopy of less than about 0.15, more preferably less than about 0.125, and even more preferably less than about 0.10.

In some embodiments, deionized water and methylene iodine (MI) contact angle (CA) may be measured at 5 points, respectively, across a 4-inch wafer were evaluated by AST Optima. The surface energies then can be calculated using the Owens, Wendt, Rabel and Kaelble method based on the water and MI contact angle values. Preferably, the polar energy of the baked underlayer is from about 5 mN/m² to about 50 mN/m², more preferably from about 15 mN/m² to about 35 mN/m². Preferably, the dispersive energy of the underlayer is from about 20 mN/m² to about 50 mN/m², more preferably from about 25 mN/m² to about 40 mN/m².

After the underlayer 18 is formed, a photoresist layer 20 (i.e., imaging layer) having an upper surface 21 is formed on underlayer 18. The preferred photoresist layer 20 is an EUV photoresist, and any commercial EUV photoresist composition can be utilized to form photoresist layer 20. In one embodiment, the photoresist layer 20 is a chemically amplified resist (CAR). In another embodiment, the photoresist layer 20 is a non-chemically amplified resist. In one embodiment, the non-chemically amplified photoresist includes a metal, such as those selected from the group consisting of titanium, zinc, tin, hafnium, zirconium, indium, vanadium, cobalt, molybdenum, tungsten, aluminum, gallium, silicon, germanium, phosphorous, arsenic, yttrium, lanthanum, cerium, lutetium, and mixtures of the foregoing. In another embodiment, the photoresist layer 20 comprises a metal oxide or organometallic compound in the photoresist composition, with suitable metals for the metal oxide (e.g., tin oxide resist, such as those commercially available from Inpria, Inc.) and/or organometallic compound being the same as those listed above.

In some embodiments, the photoresist layer 20 is substantially free of metal. That is, the metal content of the photoresist 20 is less than about 0.005% by weight, preferably less than about 0.001% by weight, and more preferably about 0% by weight, based upon the total weight of the photoresist layer 20 taken as 100% by weight.

Suitable EUV photoresists are available from several commercial suppliers including JSR, TOK, Sumitomo, LAM, Shin Etsu, FujiFilm, Inpria (such as YATU or YAQA metal oxide resists), Irresistible Materials, and Zeon.

Regardless of the photoresist type, the photoresist layer 20 can be formed by any conventional method, with one preferred method being spin coating the photoresist composition at speeds of about 350 rpm to about 4,000 rpm (preferably about 1,000 rpm to about 2,500 rpm) and for a time period of about 10 seconds to about 60 seconds (preferably about 10 seconds to about 30 seconds). The photoresist layer 20 is then optionally post-application baked (“PAB”) at a temperature of at least about 70° C., preferably about 80° C. to about 180° C., and more preferably about 100° C. to about 180° C., for about 30 seconds to about 120 seconds. The average thickness of the photoresist layer 20 after baking is typically about 5 nm to about 120 nm, preferably about 10 nm to about 50 nm, and more preferably about 20 nm to about 40 nm.

Referring to FIG. 1(C), a mask 22 is positioned above upper surface 21 of the photoresist layer 20. The mask 22 has exposure portions 24 designed to permit the radiation to reflect from (in the case of EUV radiation) or pass through (in the case of non-EUV radiation) the mask and contact the surface 21 of the photoresist layer 20, thus creating exposed areas 26 on and/or in photoresist layer 20. Mask 22 also includes nonexposure portions 28, which are designed to absorb or block the radiation to prevent the radiation from contacting surface 21 of the photoresist layer 20 in certain areas (i.e., unexposed areas 30), thus resulting in selective exposure of photoresist layer 20. Those skilled in the art will readily understand that the type of mask and the arrangement of reflecting and absorbing portions (i.e., exposure portions 24 and nonexposure portions 28) is designed based upon a desired pattern to be formed in the photoresist layer 20, and ultimately in underlayer 18, any intermediate layers 16, and the substrate 12.

The exposure wavelengths are preferably less than about 20 nm, preferably about 11 nm to about 14 nm, and more preferably about 13.5 nm, i.e., EUV exposure wavelengths.

It will be appreciated that the underlayers 18 as described herein allow for a dose reduction as compared to prior art underlayers. For example, using an underlayer 18 formulated as described herein can result in a dose reduction of about 4 mJ/cm² or more, preferably about 5 mJ/cm² or more, more preferably about 6.5 mJ/cm² or more, and even more preferably about 8 mJ/cm² or more, as compared to the dose that would be required by the same formulation but without the salt. In the same or different embodiments, the use of underlayer 18 results in a dose reduction of about 8% or more, preferably about 10% or more, and more preferably about 13% or more, as compared to the dose that would be required by the same formulation but without the ionic compound, ionic moiety, or pre-ionic compound. In either case, that dose reduction is achieved while maintaining a usable process window, improving the usable process window, and/or maintaining the same or better bridge and margin collapse.

Regardless of the degree of dose reduction, in some embodiments the typical exposure dose is about 5 mJ/cm² to about 100 mJ/cm², preferably from about 10 mJ/cm² to about 80 mJ/cm², and more preferably from about 20 mJ/cm² to about 60 mJ/cm². In other embodiments, the exposure dose is about 5 mJ/cm² to about 80 mJ/cm², preferably about 10 mJ/cm² to about 60 mJ/cm², and more preferably about 20 mJ/cm² to about 55 mJ/cm².

After exposure, the photoresist layer 20 is optionally subjected to a post-exposure bake (PEB) at a temperature of less than about 220° C., preferably about 60° C. to about 200° C., and more preferably about 80° C. to about 180° C., for about 20 seconds to about 120 seconds, and preferably about 30 seconds to about 90 seconds. The time and temperature can vary depending on the specific photoresist.

The photoresist layer 20 is then contacted with a developer to form a pattern 32 in the photoresist layer 20′ (FIG. 1(D)), with the pattern 32 including trenches 34 and raised features 36. Depending upon whether the photoresist used is positive-working or negative-working, the developer either removes the exposed portions of the photoresist layer 20′ or removes the unexposed portions of the photoresist layer 20′ to form the pattern. The pattern 32 is then transferred to the underlayer 18, any present intermediate layers 16 (e.g., hardmask layer), and finally the substrate 12. This pattern transfer can take place via plasma etching (e.g., CF₄ etchant, O₂ etchant) or a wet etching or developing process. In embodiments where the pattern is transferred from the photoresist layer 20′ to the substrate 12 via etching, it is preferred that the etch rate of the underlayer 18 relative to the EUV photoresist being used (e.g., a CAR photoresist, a non-CAR photoresist, or an organometallic photoresist) is at least about 1×, and preferably about 1.5× to about 2×. For example, the etch rate of the underlayer in O₂ is preferably in the range of about 2 nm/see to about 6 nm/sec.

Regardless of whether pattern transfer is effected by etching or by developing, the resulting features can have high resolutions and little to no bridging, which can be determined via visual observation of SEM images, and/or by using a brightfield inspection tool (e.g., KLA-Tencor 2139, by KLA Instruments) to look for defects in patterns. For example, in some embodiments, resolutions of less than about 40 nm half pitch, and preferably less than about 28 nm half pitch, more preferably less than about 20 nm half pitch, and still more preferably less than about 14 nm half pitch can be achieved with the inventive method. In other embodiments, resolutions of less than about 20 nm half pitch, and preferably less than 15 nm half pitch, can be achieved with the inventive method.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Synthesis of Copolymer of 4-Vinylpyridine/Glycidyl Methacrylate/Styrene/Methyl Acrylate

To a 250 mL three-neck flask, 0.36 grams of 4-vinylpyridine (Sigma-Aldrich, St Louis, MO) 4.52 grams of glycidyl methacrylate (Sigma-Aldrich, St Louis, MO), 2.98 grams of styrene, and 4.41 grams of methyl methacrylate (Sigma-Aldrich, St Louis, MO) were added, along with 0.09 gram of azobisisobutyronitrile (AIBN, Sigma-Aldrich, St Louis, MO) and 69.83 grams of propylene glycol methyl ether acetate (PGMEA, Sigma-Aldrich, St Louis, MO). The contents of the flask were stirred at 450 rpm under nitrogen for 30 minutes. The flask was placed in a pre-heated oil bath at 70° C. with stirring at 450 rpm for 16 hours. The mixture was allowed to cool to room temperature and then bottled. The solids content was ˜15.0% by weight.

### Example 2

### Synthesis of Copolymer of 4-Vinylpyridine/Glycidyl Methacrylate/Benzyl Methacrylate

To a 250-mL three-neck flask, 0.07 gram of 4-vinylpyridine, 1.30 grams of glycidyl methacrylate, and 6.37 grams of benzyl methacrylate were added, along with 0.08 gram of AIBN and 44.29 grams of PGMEA. The contents of the flask were stirred under nitrogen for 30 minutes. The flask was placed in a pre-heated oil bath at 70° C. and stirred at 450 rpm for 16 hours to complete the reaction. The mixture was allowed to cool to room temperature and was bottled. The solids content was ˜15.01% by weight.

### Example 3

### Synthesis of Copolymer of 4-Vinylpyridine/Glycidyl Methacrylate/Benzyl Methacrylate

To a 250-mL three-neck flask, 0.14 gram of 4-vinylpyridine, 2.31 grams of glycidyl methacrylate, and 5.04 grams of benzyl methacrylate were added, along with 0.072 gram of AIBN and 42.68 grams of PGMEA. The contents of the flask were stirred under nitrogen for 30 minutes. The flask was placed in a pre-heated oil bath at 70° C. and stirred at 450 rpm for 16 hours to complete the reaction. The mixture was allowed to cool to room temperature and was bottled. The solids content was ˜15.0% by weight.

### Example 4

### Synthesis of Copolymer of 4-Vinylpyridine/Benzyl Methacrylate/Glycidyl Methacrylate

To a 250-mL three-neck flask, 0.20 gram of 4-vinylpyridine, 1.93 grams of glycidyl methacrylate, and 4.04 grams of benzyl methacrylate were added along with 0.06 gram of AIBN and 55.65 grams of PGMEA. The contents of the flask were stirred under nitrogen for 30 minutes. The flask was placed in a pre-heated oil bath at 70° C. and stirred at 450 rpm for 16 hours to complete the reaction. The mixture was allowed to cool to room temperature and was bottled. The solids content was ˜10.07% by weight.

### Example 5

### Synthesis of Copolymer of 4-Vinylpyridine/Glycidyl Methacrylate/Hydroxypropyl Methacrylate/n-Butyl Methacrylate

To a 250-mL three-neck flask, 0.21 gram of 4-vinylpyridine, 0.31 gram of glycidyl methacrylate, 2.18 grams of n-butyl methacrylate, and 6.44 grams of hydroxypropyl methacrylate were added along with 0.09 gram of AIBN and 51.88 grams of PGMEA. The contents of the flask were stirred under nitrogen for 30 minutes. The flask was placed in a pre-heated oil bath at 70° C. and stirred at 450 rpm for 16 hours to complete the reaction. The mixture was allowed to cool to room temperature and was bottled. The solids content was ˜15.1% by weight.

### Example 6

### Synthesis of Copolymer of 4-Vinylpyridine/Glycidyl Methacrylate/Hydroxypropyl Methacrylate/Methyl Methacrylate

To a 250-mL three-neck flask, 0.21 gram of 4-vinylpyridine, 0.29 gram of glycidyl methacrylate, 1.54 gram of methyl methacrylate, 6.43 grams of hydroxypropyl methacrylate, 0.08 gram of AIBN, and 48.45 grams of propylene glycol methyl ether (PGME) were added. The contents of the flask were stirred under nitrogen for 30 minutes after which the flask was immersed in an oil bath at 70° C. and stirred at 450 rpm for 16 hours to complete the reaction. The mixture was allowed to cool to room temperature and was bottled. The solids content was ˜15.01% by weight.

### Example 7

### Synthesis of Copolymer of 4-Vinylpyridine/Glycidyl Methacrylate/Hydroxypropyl Methacrylate/t-Butyl Methacrylate

To a 250-mL three-neck flask, 0.20 gram of 4-vinylpyridine, 0.29 gram of glycidyl methacrylate, 2.19 grams of t-butyl methacrylate, 6.41 grams of hydroxypropyl methacrylate, 0.087 gram of AIBN, and 51.81 grams of PGME were added. The contents of the flask were stirred under nitrogen for 30 minutes after which the flask was immersed in a preheated oil bath at 70° C. and stirred at 450 rpm for 16 hours to complete the reaction. The mixture was allowed to cool to room temperature and was bottled. The solids content was ˜15.05% by weight.

### Example 8

### Synthesis of Copolymer of 4-Vinylpyridine/Hydroxypropyl Methacrylate

To a 250-mL three-neck flask 1.20 grams of 4-vinylpyridine, 14.90 grams of hydroxypropyl methacrylate, 0.16 gram of azobisisobutyronitrile (AIBN), and 91.65 grams of propylene glycol methyl ether (PGME) were added. The contents of the flask were stirred under nitrogen for 30 minutes, and then the flask was immersed in a preheated oil bath at 70° C., stirred at 450 rpm, and held for 16 hours to complete the reaction. The mixture was allowed to cool to room temperature and was bottled. Solids content was ˜15.07% by weight.

### Example 9

### Synthesis of Copolymer of 4-Vinylpyridine/Glycidyl Methacrylate/Hydroxypropyl Methacrylate/Methyl Methacrylate

To a 250-mL three-neck flask 0.20 gram of 4-vinylpyridine, 5.78 grams of 2-hydroxyethoyl methacrylate, 1.54 grams of methyl methacrylate, 0.31 gram of glycidyl methacrylate, 0.234 gram of azobisisobutyronitrile (AIBN), and 45.41 grams of propylene glycol methyl ether (PGME) were added. The contents of the flask were stirred under nitrogen for 30 minutes, and then the flask was immersed in a preheated oil bath at 70° C., stirred at 450 rpm, and held for 16 hours with continued stirring to complete the reaction. The mixture was allowed to cool to room temperature and was bottled. Solids content was ˜15.08% by weight.

### Example 10

### Synthesis of Copolymer of 4-Vinylpyridine/Glycidyl Methacrylate/Hydroxyethyl Methacrylate/Methyl Methacrylate

To a 250-mL three-neck flask, 0.20 gram of 4-vinylpyridine, 3.88 grams of 2-hydroxyethoyl methacrylate, 3.01 grams of methyl methacrylate, 0.29 gram of glycidyl methacrylate, 0.22 gram of AIBN, and 43.32 grams of PGME were added. The contents of the flask were stirred under nitrogen for 30 minutes. The flask was then immersed in a pre-heated oil bath at 70° C., stirred at 450 rpm, and held for 16 hours with continued stirring to complete the reaction. The mixture was allowed to cool to room temperature and was bottled. The solids content was ˜14.93% by weight.

### Example 11

### Synthesis of Copolymer of 4-Vinylpyridine/Glycidyl Methacrylate/Hydroxyethyl Acrylate/Methyl Methacrylate

To a 250-mL three-neck flask 0.20 gram of 4-vinylpyridine, 5.26 grams of 2-hydroxyethyl acrylate, 1.55 grams of methyl methacrylate, 0.28 gram of glycidyl methacrylate, 0.072 gram of AIBN, and 40.98 grams of PGME were added. The contents of the flask were stirred under nitrogen for 30 minutes after which the flask was immersed in a preheated oil bath at 70° C., stirred at 450 rpm, and held for 16 hours with continued stirring to complete the reaction. The mixture was allowed to cool to room temperature and was bottled. The solids content was ˜15.23% by weight.

### Example 12

### Synthesis of Copolymer of 4-Vinylpyridine/Glycidyl Methacrylate/t-Butyl Methacrylate

To a 250-mL three-neck flask, 0.20 gram of 4-vinylpyridine, 3.25 grams of t-butyl methacrylate, 1.90 grams of glycidyl methacrylate, 0.054 gram of AIBN, and 48.51 grams of PGMEA were added. The contents of the flask were stirred under nitrogen for 30 minutes. The flask was then immersed in a preheated oil bath at 70° C., stirred at 450 rpm, and held for 16 hours with continued stirring to complete the reaction. The mixture was allowed to cool to room temperature and was bottled. The solids content was ˜10.03% by weight.

### Example 13

### Synthesis of Copolymer of 4-Vinylpyridine/Glycidyl Methacrylate/Methyl Methacrylate

To a 250-mL three-neck flask, 0.30 gram of 4-vinylpyridine, 3.43 grams of methyl methacrylate, 2.84 grams of glycidyl methacrylate, 0.069 gram of AIBN, and 59.76 grams of PGMEA were added. The contents of the flask were stirred under nitrogen for 30 minutes, and then the flask was immersed in a preheated oil bath at 70° C., stirred at 450 rpm, and held for 16 hours with continued stirring to complete the reaction. The mixture was allowed to cool to room temperature and was bottled. The solids content was ˜10.00% by weight.

### Example 14

### Synthesis of Polyhydroxypropyl Methacrylate

To a 250 mL three-neck flask, 12.51 grams of hydroxypropyl methacrylate, 0.13 gram of AIBN, and 71.57 grams of PGME were added. The contents of the flask were stirred under nitrogen for 30 minutes, and then the flask was immersed in a preheated oil bath at 70° C., stirred at 450 rpm, and held for 16 hours to complete the reaction. The mixture was allowed to cool to room temperature and was bottled. The solids content was ˜15.01% by weight.

### Example 15

### Synthesis of Polyglycidyl Methacrylate

To a 250 mL three-neck flask, 12.53 grams of glycidyl methacrylate, 0.12 gram of AIBN, and 71.50 grams of PGMEA were added. The contents of the flask were stirred under nitrogen for 30 minutes. The flask was then immersed in a preheated oil bath at 70° C., stirred at 450 rpm, and held for 16 hours to complete the reaction. The mixture was allowed to cool to room temperature and was bottled. The solids content was ˜15.04% by weight.

### Example 16

### Synthesis of Copolymer of 2-Vinylpyridine/Glycidyl Methacrylate/Hydroxypropyl Methacrylate/n-Butyl Methacrylate

To a 250-mL three-neck flask, 0.21 gram of 2-vinylpyridine, 2.20 grams of n-butyl methacrylate, 0.31 gram of glycidyl methacrylate, 6.52 grams of hydroxypropyl methacrylate, 0.09 gram of AIBN, and 51.85 grams of PGME were added. The contents of the flask were stirred under nitrogen for 30 minutes. The flask was then immersed in a preheated oil bath at 70° C., stirred at 450 rpm, and held for 16 hours with continued stirring to complete the reaction. The mixture was allowed to cool to room temperature and was bottled. The solids content was ˜15.25% by weight.

### Example 17

### Synthesis of Copolymer of 2-(Dimethylamino)Ethyl Methacrylate/Glycidyl Methacrylate/n-Butyl Methacrylate

To a 250-mL three-neck flask, 1.01 grams of 2-(dimethylamino)ethyl methacrylate, 6.92 grams of butyl methacrylate, 0.42 gram of glycidyl methacrylate, 0.083 gram of AIBN, and 47.55 grams of PGMEA were added. The contents of the flask were stirred under nitrogen for 30 minutes. The then the then flask was immersed in a preheated oil bath at 70° C., stirred at 450 rpm, and held for 16 hours with continued stirring to complete the reaction. The mixture was allowed to cool to room temperature and was bottled. The solids content was ˜15.06% by weight.

### Example 18

### Formulation of EUV Underlayer 6

An EUV underlayer formulation was prepared by mixing 4.54 grams of the polymer solution from Example 2 with 2.15 grams of a 1.5% by weight solution of TAG-2689 (King Industries, Norwalk, CT) in PGME, 20.64 grams of PGME, and 5.89 grams of PGMEA to make a solution having a solids content of 2.0% by weight. The solution was mixed well for 4 hours and then filtered through a 0.1-μm PTFE filter. The resulting formulation was spin-coated onto a 4-inch silicon wafer at 1,500 rpm for 60 seconds and then baked on a hot plate at 205° C. for 60 seconds. The resulting cured film was measured by ellipsometry to be 595 Å thick and was unable to be removed by PGME and PGMEA (tested separately). The formulation was then diluted with a 70/30 mixture of PGME/PGMEA to ˜0.05%, and the spin-coating repeated on another silicon wafer to yield a ˜2.0 nm film for EUV lithography test. The film was tested as an EUV underlayer at IMEC with Inpria MOR resist YAQA9000. The best dose for P/L=28/14 was 62.4 mJ.

### Example 19

### Formulation of EUV Underlayer 7

An EUV underlayer formulation was prepared by mixing 4.54 grams of the polymer solution from Example 3 with 2.31 grams of a 1.5% by weight solution of TAG-2689 in PGME, 22.18 grams of PGME, and 6.63 grams of PGMEA to make a solution having a solids content of 2.0% by weight. The solution was mixed well for 4 hours and then filtered through a 0.1-μm PTFE filter. The resulting formulation was spin-coated onto a 4-inch silicon wafer at 1,500 rpm for 60 seconds and then baked on a hot plate at 205° C. for 60 seconds. The resulting cured film was measured by ellipsometry to be 508 Å thick and was unable to be removed by PGME and PGMEA (tested separately). The formulation was then diluted with a 70/30 mixture of PGME/PGMEA to ˜0.05%, and the spin coating process repeated on another silicon wafer to yield a ˜1.8 nm film for EUV lithography test. The film was tested at IMEC with Inpria MOR resist YAQA9000. The best dose for P/L=28/14 was 54.6 mJ.

### Example 20

### Formulation of EUV Underlayer 8

An EUV underlayer formulation was prepared by mixing 1.52 grams of the polymer solution from Example 4 with 1.55 grams of a 1.5% by weight solution of TAG-2689 in PGME, 110.47 grams of PGME, and 46.21 grams of PGMEA to make a solution having a solids content of 0.1% by weight. The solution was mixed well for 4 hours and then filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be 1.5 nm thick and was unable to be removed by PGME and PGMEA (tested separately). Due to significant dose reduction from the underlayer, the wafer was overexposed and linear regression was used to estimate the dose to size of 50 mJ/cm². The best dose for P/L=28/14 was 50.0 mJ.

### Example 21

### Formulation of EUV Underlayer 9

An EUV underlayer formulation was prepared by mixing 5.04 grams of the polymer solution from Example 5 with 2.54 grams of a 1.5% by weight solution of TAG-2689 in PGME, 52.55 grams of PGME, and 19.37 grams of PGMEA to make a solution having a solids content of 1.0% by weight. The solution was mixed well for 4 hours and then filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be 191 Å thick and was unable to be removed by PGME and PGMEA (tested separately). The formulation was diluted with a 70/30 mixture of PGME/PGMEA to ˜0.05% and the spin coating process repeated on another silicon wafer to yield a ˜1.8 nm film for EUV lithography test. The film was tested at IMEC with Inpria MOR resist YAQA9000. The best dose for P/L=28/14 was 46.1 mJ.

### Example 22

### Formulation of EUV Underlayer A

An EUV underlayer formulation was prepared by mixing 1.61 grams of the polymer solution from Example 6 with 0.83 gram of a 1.5% by weight solution of TAG-2689 in PGME, 87.58 grams of PGME, and 36.75 grams of PGMEA to make a solution having a solids content of 0.2% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜5.0 nm thick and was unable to be removed by PGME and PGMEA (tested separately). The same formulation was spin-coated onto another 4-inch silicon wafer and baked in the same way. The resulting film was tested at IMEC with Inpria MOR resist YAQA9000, best dose for P/L=26/13 was 44.8 mJ.

### Example 23

### Formulation of EUV Underlayer B

An EUV underlayer formulation was prepared by mixing 1.63 grams of the polymer solution from Example 7 with 0.81 gram of a 1.5% by weight solution of TAG-2689 in PGME, 87.75 grams of PGME, and 36.77 grams of PGMEA to make a solution having a solids content of 0.20% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜5.0 nm thick and was unable to be removed by PGME and PGMEA (tested separately). The same formulation was spin-coated onto another 4-inch silicon wafer and baked in the same way. The resulting film was tested at IMEC with Inpria MOR resist YAQA9000, best dose for P/L=26/13 was 44.8 mJ.

### Example 24

### Formulation of EUV Underlayer C

An EUV underlayer formulation was prepared by mixing 4.01 grams of the polymer solution from Example 8 with 12.06 grams of a 0.5% by weight solution of p-TSA in PGME, 18.51 grams of PGME, and 9.72 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜4.9 nm thick and was unable to be removed by PGMEA. The formulation was diluted with a 70/30 mixture of PGME/PGMEA to ˜0.15% to yield a ˜51 Å film for EUV lithography test. The diluted formulation was spin-coated onto another 4-inch silicon wafer and baked in the same way. The resulting film was tested at imec with Inpria MOR resist YAQA9000, and the best dose for P/L=26/13 was 51.3 mJ.

### Example 25

### Formulation of EUV Underlayer 10

An EUV underlayer formulation was prepared by mixing 5.03 grams of the polymer solution from Example 16 with 2.58 grams of a 1.5% by weight solution of TAG-2689 in PGME, 30.15 grams of PGME, and 15.85 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜460 Å thick and was unable to be removed by PGMEA. The formulation was diluted with a 70/30 mixture of PGME/PGMEA to ˜0.15% to yield a ˜5.0 nm film for EUV lithography test. The diluted formulation was spin-coated onto another 4-inch silicon wafer and baked in the same way. The resulting film was tested at imec with Inpria MOR resist YATU1011, and the best dose for P/L=28/14 was 55.2 mJ.

### Example 26

### Formulation of EUV Underlayer 11

An EUV underlayer formulation was prepared by mixing 5.01 grams of the polymer solution from Example 17 with 2.57 grams of a 1.5% by weight solution of TAG-2689 in PGME, 33.88 grams of PGME, and 11.37 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜401 Å thick and was unable to be removed by PGMEA. The formulation was diluted with a 70/30 mixture of PGME/PGMEA to ˜0.15% to yield a ˜5.6 nm film for EUV lithography test. The diluted formulation was spin-coated onto another 4-inch silicon wafer and baked in the same way. The resulting film was tested at imec with Inpria MOR resist YATU1011, and the best dose for P/L=28/14 was >60.0 mJ.

### Example 27

### Formulation of EUV Underlayer 12

An EUV underlayer formulation was prepared by mixing 2.03 grams of the polymer solution from Example 8, 2.01 grams of the polymer solution from Example 14, 2.68 grams of polymer solution from Example 15, with 3.37 grams of a 1.5% by weight solution of TAG-2689 in PGME, 41.13 grams of PGME, and 19.01 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜382 Å thick and was unable to be removed by PGMEA. The formulation was diluted with a 70/30 mixture of PGME/PGMEA to ˜0.10% to yield a ˜3.6 nm film for EUV lithography test. The diluted formulation was spin-coated onto another 4-inch silicon wafer and baked in the same way. The resulting film was tested at imec with Inpria MOR resist YATU1011, best dose for P/L=28/14 was ˜50.0 mJ.

### Example 28

### Formulation of EUV Underlayer 13

An EUV underlayer formulation was prepared by mixing 1.02 grams of the polymer solution from Example 8 with 0.19 gram of 21.14% by weight solution of ECN1299 (Huntsman Advanced Materials Americas, LLC, The Woodlands, TX) in PGMEA, 1.53 grams of a 0.5% by weight solution of p-TSA in PGME, 89.85 grams of PGME, and 38.20 grams of PGMEA to make a solution having a solids content of 0.15% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜5.0 nm thick and was unable to be removed by PGMEA. The same formulation was spin-coated onto another 4-inch silicon wafer and baked in the same way. The resulting film was tested at imec with Inpria MOR resist YATU1011, and the best dose for P/L=28/14 was ˜48.7 mJ.

### Example 29

### Formulation of EUV Underlayer 14

An EUV underlayer formulation was prepared by mixing 4.01 grams of polymer solution from Example 9 with 2.51 grams of 4.87% by weight solution of Powderlink® 1174 (Cytec Industries Inc., West Paterson, NJ) in PGME, 6.05 grams of a 0.5% by weight solution of p-TSA in PGME, 22.90 grams of PGME, and 14.90 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜417 Å thick and was unable to be removed by PGMEA. The formulation was diluted with a 70/30 mixture of PGME/PGMEA to ˜0.40% to yield a −10 nm film for EUV lithography test. The diluted formulation was spin-coated onto another 4-inch silicon wafer and baked in the same way. The resulting film was tested at imec with Inpria MOR resist YATU1011, and the best dose for P/L=28/14 was 38.1 mJ.

### Example 30

### Formulation of EUV Underlayer 15

An EUV underlayer formulation was prepared by mixing 4.28 grams of the polymer solution from Example 10 with 1.99 grams of 4.87% by weight solution of Powderlink® 1174 in PGME, 6.36 grams of a 0.5% by weight solution of p-TSA in PGME, 23.27 grams of PGME, and 15.07 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜428 Å thick and was unable to be removed by PGMEA. The formulation was diluted with a 70/30 mixture of PGME/PGMEA to ˜0.40% to yield a ˜10.7 nm film for EUV lithography test. The diluted formulation was spin-coated onto another 4-inch silicon wafer and baked in the same way. The resulting film was tested at imec with Inpria MOR resist YATU1011, and the best dose for P/L=28/14 is 34.2 mJ.

### Example 31

### Formulation of EUV Underlayer 16

An EUV underlayer formulation was prepared by mixing 4.01 grams of the polymer solution from Example 11 with 3.13 grams of 4.87% by weight solution of Powderlink® 1174 in PGME, 6.13 grams of a 0.5% by weight solution of p-TSA in PGME, 23.94 grams of PGME, and 15.60 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting formulation was diluted with a 70/30 mixture of PGME/PGMEA to ˜0.45% to yield a ˜10.4 nm film for EUV lithography test. The film was tested at imec with Inpria MOR resist YATU1011, and the best dose for P/L=28/14 was ˜30 mJ.

### Example 32

### Formulation of EUV Underlayer 17

An EUV underlayer formulation was prepared by mixing 4.02 grams of the polymer solution from Example 10 with 2.13 grams of 5.0% by weight solution of Cymel® 303 (Allnex USA Inc., Alpharetta, GA) in PGME, 6.04 grams of a 0.5% by weight solution of p-TSA in PGME, 22.57 grams of PGME, and 14.60 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜452 Å thick and was unable to be removed by PGMEA. The formulation was diluted with a 70/30 mixture of PGME/PGMEA to ˜0.36% to yield a ˜10.4 nm film for EUV lithography test. The diluted formulation was spin-coated onto another 4-inch silicon wafer and baked in the same way. The resulting film was tested at imec with Inpria MOR resist YATU1011, best dose for P/L=28/14 was 39.4 mJ.

### Example 33

### Formulation of EUV Underlayer 18

An EUV underlayer formulation was prepared by mixing 8.01 grams of the polymer solution from Example 12 with 4.02 grams of a 1.00% by weight solution of p-TSA in PGME, 34.80 grams of PGME, and 9.42 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜412 Å thick and was unable to be removed by PGMEA. The formulation was diluted with a 70/30 mixture of PGME/PGMEA to ˜0.38% to yield a ˜10.2 nm film for EUV lithography test. The diluted formulation was spin-coated onto another 4-inch silicon wafer and baked in the same way. The resulting film was tested at imec with Inpria MOR resist YATU1011, and the best dose for P/L=28/14 was 34.2 mJ.

### Example 34

### Formulation of EUV Underlayer 19

An EUV underlayer formulation was prepared by mixing 8.04 grams of the polymer solution from Example 13 with 4.03 grams of a 1.00% by weight solution of p-TSA in PGME, 34.69 grams of PGME, and 9.38 grams of PGMEA to make a solution having a solids content of 1.50% by weight. The solution was mixed well for 4 hours and was filtered through a 0.1-μm PTFE filter. The formulation was spin-coated onto a 4-inch silicon wafer at 1,500 rpm for 60 seconds and then baked on a hot plate at 205° C. for 60 seconds. The resulting cured film was measured by ellipsometry to be ˜345 Å thick and was unable to be removed by PGMEA. The formulation was diluted with a 70/30 mixture of PGME/PGMEA to ˜0.43% solids to yield a ˜9.9 nm film for EUV lithography test. The diluted formulation was spin-coated onto another 4-inch silicon wafer and baked in the same way. The resulting film was tested at imec with Inpria MOR resist YATU1011, and the best dose for P/L=28/14 was 34.2 mJ.

### Example 35

### Lithography Results

Formulations were spin-coated onto a 4-inch silicon wafer at 1,500 rpm for 60 seconds and then baked on a hot plate at 205° C. for 60 seconds. The resulting films were tested at imec with Inpria MOR resist YATU1011. Table 1 shows the thickness and best dose for each of Examples 18-24 as well as the line width roughness (LWR) and line edge roughness (LER), and Table 2 shows the same information for Examples 25-30. It was discovered that a damaged reticle had been used for Examples 18-24, so Examples 25-30 used a different (undamaged) reticle to generate the same pattern in the MOR layer (P28/14 L/S), and this reticle required ˜25% lower dose than the reticle used in Examples 18-24. This reduction in dose is common between both MOR and CAR and comes from lower reflectivity.

TABLE 1
Examples of Film Thickness and Best Dose (old reticle)

| | Thickness, nm | Best dose, mJ/cm² | LWR, nm | LER, nm |
|---|---|---|---|---|
| Sample 18 | ~2.0 | 62.4 | 3.14 | 2.29 |
| Sample 19 | ~1.8 | 54.6 | 3.1 | 2.33 |
| Sample 20 | ~1.5 | estimated ~50.0 | | |
| Sample 21 | ~1.8 | 46.1 | 3.34 | 2.44 |
| Sample 22 | ~5.0 | 44.8 | 3.42 | 2.57 |
| Sample 23 | ~4.0 | 44.8 | 3.33 | 2.49 |
| Sample 24 | ~4.0 | 51.3 | 3.39 | 2.44 |

TABLE 2
Examples of Film Thickness and Best Dose (new reticle)

| | Thickness, nm | Best dose, mJ/cm² | LWR, nm | LER, nm |
|---|---|---|---|---|
| Sample 25 | ~10.9 | 38.1 | 3.08 | 2.28 |
| Sample 26 | ~10.7 | 34.2 | 3.26 | 2.4 |
| Sample 27 | ~10.4 | estimated ~30.0 | | |
| Sample 28 | ~10.4 | 39.4 | 3.17 | 2.24 |
| Sample 29 | ~10.2 | 34.2 | 3.56 | 2.58 |
| Sample 30 | ~9.9 | 34.2 | 3.27 | 2.4 |

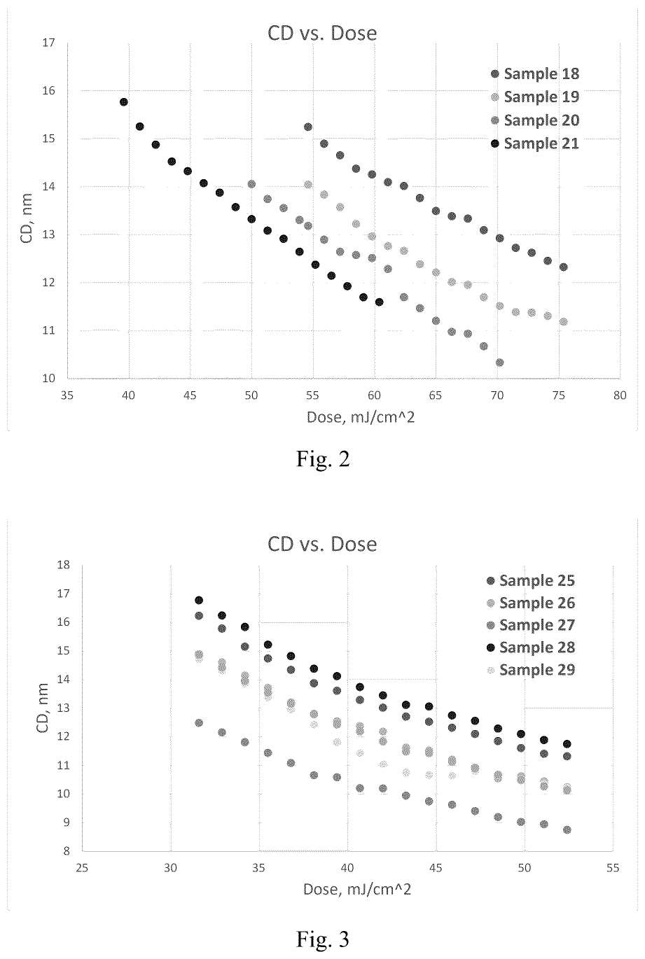

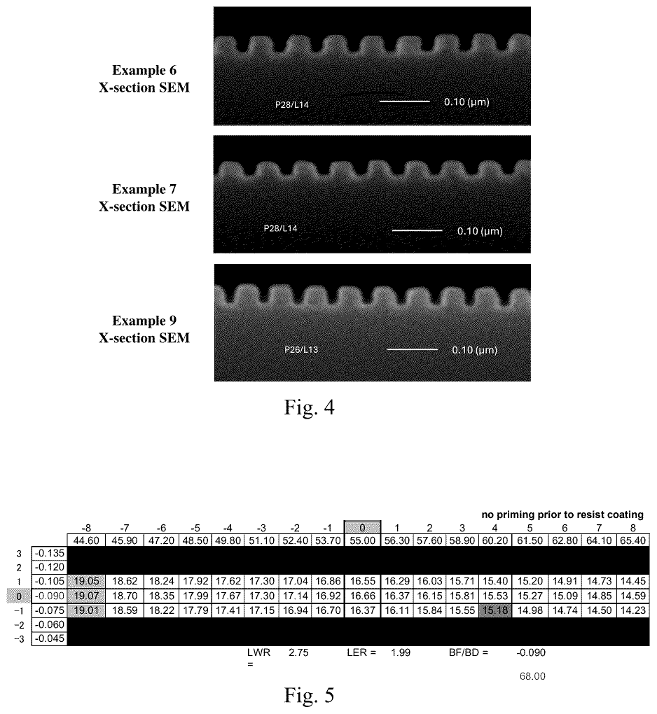

FIG. 2 shows the CD vs. dose for each of the EUV underlayers tested in Examples (or “Samples”) 18-21. FIG. 3 shows the CD vs. dose for each of the EUV underlayers tested in Examples (or “Samples”) 25-29. FIG. 4 shows cross section SEM images of lines formed by EUV lithography using the underlayers of Examples 18-21 with the previously described resist MOR photoresist. Doses that are designated as “estimated” were determined by extrapolating the dose matrix.

### Example 36

### Synthesis of Homopolymer of N-(Butoxymethyl)Acrylamide

To a 250-mL single-neck flask 23.582 grams of N-(butoxymethyl)acrylamide, 0.047 gram of AIBN, 0.9315 gram of 4-cyano-4(((dodecylthio)carbonothioyl)thio)pentanoic acid, and 98.24 grams of PGME were added. The contents of the flask were sealed with a septum and sparged with nitrogen for 10 minutes, and then the flask was immersed in a preheated oil bath at 70° C., stirred at 400 rpm, and held for 24 hours with continued stirring to complete the reaction. The mixture was allowed to cool to room temperature and was bottled. Solids content was ˜20.0% by weight.

### Example 37

### Synthesis of Copolymer of N-(Butoxymethyl)Acrylamide/4-Vinyl Pyridine

To a 100-mL single-neck flask 16.979 grams of N-(butoxymethyl)acrylamide, 1.262 grams of 4-vinyl pyridine, 0.0746 gram of azobisisobutyronitrile (AIBN), 1.468 grams of 4-cyano-4-(((dodecylthio)carbonothioyl)thio)pentanoic acid, and 29.67 grams of propylene glycol methyl ether (PGME) were added. The contents of the flask were sealed with a septum and sparged with nitrogen for 10 minutes, and then the flask was immersed in a preheated oil bath at 70° C., stirred at 350 rpm, and held for 24 hours with continued stirring to complete the reaction. The mixture was allowed to cool to room temperature and was bottled. Solids content was ˜40.0% by weight.

### Example 38

### Formulation of EUV Underlayer 20

An EUV underlayer formulation was prepared by mixing 2.21 grams of the polymer solution from Example 36 with 1.77 grams of a 1.00% by weight solution of pyridinium p-toluene sulfonate (PpTS) in PGME, 176.07 grams of PGME, and 19.95 grams of PGMEA to make a solution having a solids content of 0.23% by weight. The solution was mixed well for 1 hour and then filtered through a 0.1-μm PTFE filter. The formulation was spin-coated onto a 4-inch silicon wafer at 1,500 rpm for 60 seconds and then baked on a hot plate at 250° C. for 60 seconds. The resulting cured film was measured by ellipsometry to be ˜5.0 nm thick and was unable to be removed by PGME. The formulation was spin-coated onto another 4-inch silicon wafer, baked in the same way, and evaluated by EUV lithography test. The film was tested at IMEC with Inpria MOR resist YAQA9000. The focus exposure matrix is shown in FIG. 5. The best dose for P/L=28/14 was 68.0 mJ.

### Example 39

### Formulation of EUV Underlayer 21

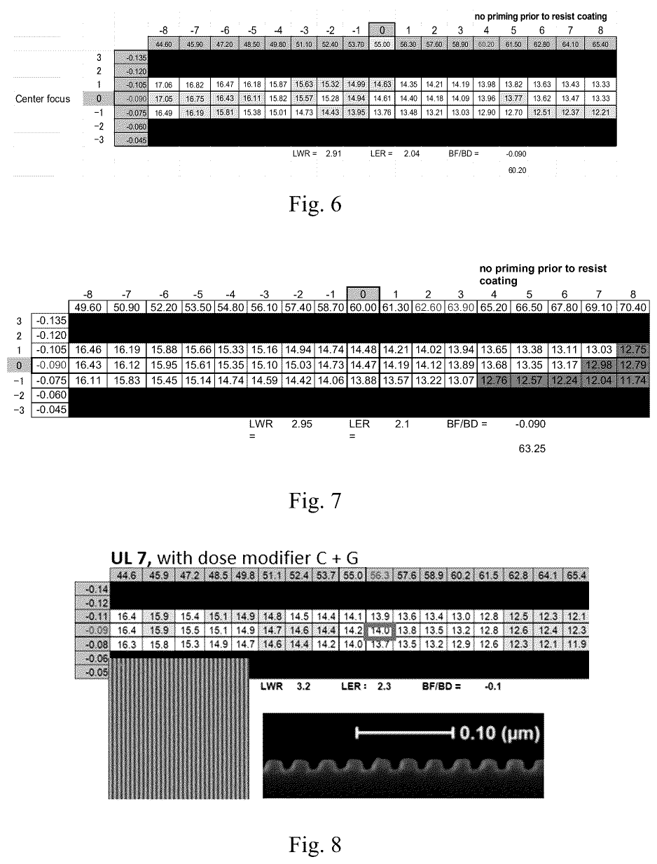

An EUV underlayer formulation was prepared by mixing 0.96 grams of the copolymer solution from Example 37 with 1.54 grams of a 1.00% by weight solution of PpTS in PGME, 177.54 grams of PGME, and 19.96 grams of PGMEA to make a solution having a solids content of 0.20% by weight. The solution was mixed well for 1 hour and then filtered through a 0.1-μm PTFE filter. The formulation was spin-coated onto a 4-inch silicon wafer at 1,500 rpm for 60 seconds and then baked on a hot plate at 250° C. for 60 seconds. The resulting cured film was measured by ellipsometry to be ˜5.0 nm thick and was unable to be removed by PGME. The formulation was spin-coated onto another 4-inch silicon wafer, baked in the same way, and evaluated by EUV lithography test. The film was tested at IMEC with Inpria MOR resist YAQA9000. The focus exposure matrix is shown in FIG. 6. The best dose for P/L=28/14 was 60.2 mJ.

### Example 40

### Formulation of EUV Underlayer 22

An EUV underlayer formulation was prepared by mixing 2.29 grams of the polymer solution from Example 36 with 1.83 grams of a 1.00% by weight solution of PpTS in PGME, 4.58 grams of a 0.5% by weight solution of 1-(3-sulfopropyl)-2-vinylpyridinium hydroxide inner salt (SPV) in 90:10 PGME:deionized water mixture, 171.81 grams of PGME, 18.95 grams of PGMEA, and 0.54 gram of deionized water to make a solution having a solids content of 0.25% by weight. The solution was mixed well for 1 hour and was filtered through a 0.1-μm PTFE filter. The formulation was spin-coated onto a 4-inch silicon wafer at 1,500 rpm for 60 seconds and then baked on a hot plate at 250° C. for 60 seconds. The resulting cured film was measured by ellipsometry to be ˜5.0 nm thick and was unable to be removed by PGME. The formulation was spin-coated onto another 4-inch silicon wafer, baked in the same way, and evaluated by EUV lithography test. The film was tested at IMEC with Inpria MOR resist YAQA9000. The focus exposure matrix is shown in FIG. 7. The best dose for P/L=28/14 was 63.3 mJ.

### Example 41

### Formulation of EUV Underlayer 23

An EUV underlayer formulation was prepared by mixing 0.92 grams of the copolymer solution from Example 37 with 1.47 grams of a 1.00% by weight solution of PpTS in PGME, 3.67 grams of a 0.5% by weight solution of SPV in 90:10 PGME:deionized water mixture, 174.35 grams of PGME, 18.96 grams of PGMEA, and 0.63 gram of deionized water to make a solution having a solids content of 0.20% by weight. The solution was mixed well for 1 hour and then filtered through a 0.1-μm PTFE filter. The formulation was spin-coated onto a 4-inch silicon wafer at 1,500 rpm for 60 seconds and then baked on a hot plate at 250° C. for 60 seconds. The resulting cured film was measured by ellipsometry to be ˜5.0 nm thick and was unable to be removed by PGME. The formulation was spin-coated onto another 4-inch silicon wafer, baked in the same way, and evaluated by EUV lithography test. The film was tested at IMEC with Inpria MOR resist YAQA9000. The best dose for P/L=28/14 was 55.0 mJ.

### Example 42

### Synthesis of Compound 1

In a clean, single-neck round bottom flask equipped with a stir bar, 5.43 g of (propylene glycol methyl ether) PGME and 1.45 g of 3-iodopropyltrimethoxysilane were added. The solution was then mixed for five minutes. In a separate vial, 10 g of PGME and 1.03 g of imidazole were vigorously shaken, until all of the imidazole was dissolved into the PGME. This mixture was then added dropwise into the round bottom flask and stirred constantly at 380 rpm. Next, the flask was plugged with a stopper and mixed for six hours at room temperature. After mixing for six hours, the solution was transferred from the flask into a clean Aicello bottle and stored in a freezer. A small aliquot of the solution was then taken for a ¹H nuclear magnetic resonance (NMR) analysis. The final solution was recorded to be about ten percent solid. The resulting polymer with the salt bound thereto is shown below.

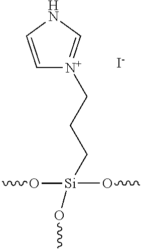

### Example 43

### Formulation of EUV Underlayer A

To a clean Aicello bottle, 0.2600 g of Compound 1, 2.500 g of DI water, and 22.26 g of PGME were added. The solution was mixed for an hour before use. The final percent solids was recorded to be 0.1 percent, resulting in a formulation tailored to produce a spin-coated underlayer having a thickness of about 1.2 nm.

EUV lithography testing of Underlayer A carried out as described previously exhibited a dose of 54.6 mJ with respect to P28 lines. When compared to a non-ionic, silicon-containing underlayer tested under similar conditions, a dose reduction of approximately 20% was observed. The focus exposure matrix and an SEM image of the formed features are shown in FIG. 8.

### Example 44

### Synthesis of Compound 4

In a clean, three-neck round bottom flask equipped with a stir bar, 80.44 g of PGME and 12.93 g of n-(3-triethoxysilylpropyl)-4-hydroxybutyramide (HATEOS) were added. This solution was mixed for 5 minutes. In a separate vial, 6.81 g of 0.01M HNO3 was weighed and then added dropwise to the round bottom flask while stirring constantly. The flask was plugged with a stopper and allowed to stir for 30 minutes at 380 rpm and room temperature. After 30 minutes, the flask was connected to a reflux setup and equipped with nitrogen gas flow. The mixture was run for 10 hours at 70° C., including time to rise up to temperature within the 10 hours. The solution was then allowed to cool to room temperature, bottled, and stored in a freezer. The resulting polymer had the structure shown below.

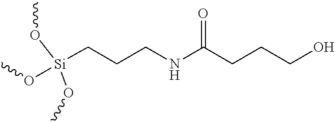

### Example 45

### Formulation of EUV Underlayer C

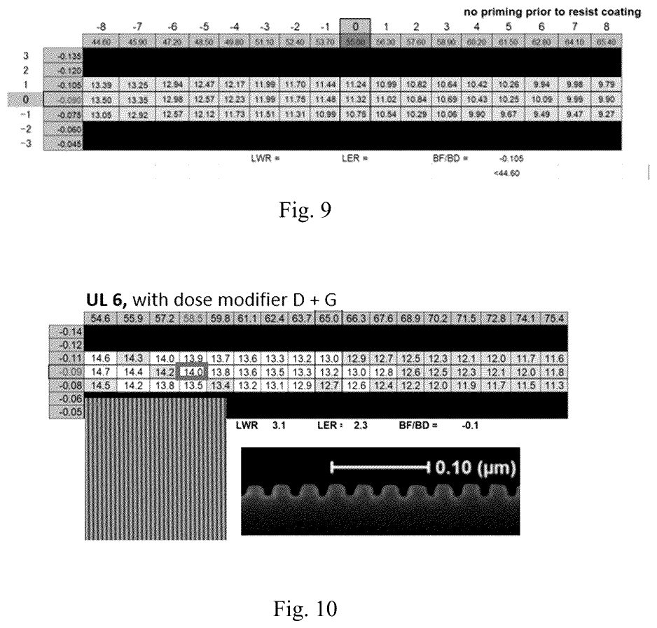

To a clean Aicello bottle, 4.2569 g of Compound 1 from Example 42 (10% solids in PGME), 1.5799 g of Compound 4 from Example 44 (9.04% solids in PGME), 11.297 g of pyridinium p-toluene sulfonate (PpTS) solution (0.2% in PGME), and 63.6441 g of PGME were added. The solution was mixed for an hour before use. This material was spin-coated at 1,500 rpm for 60 seconds and baked at 160° C. for 60 seconds to generate a film having a thickness of 10 nm. The focus exposure matrix is shown in FIG. 9.

### Example 46

### Synthesis of Compound 5

To a clean single neck round-bottom flask, 32.72 g of PGME and 2.08 g of N,N-(dimethylaminopropyltrimethoxysilane) (DMAPTMS) were added, and the solution was stirred for 10 minutes. Next, 1.56 g of iodoethane was weighed in a separate container then added dropwise into the flask, while stirring constantly. The resulting mixture was stirred at room temperature for 24 hours. The solution was then bottled and stored in a freezer. The resulting compound had the structure shown below.

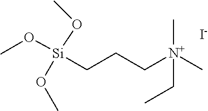

### Example 47

### Formulation of EUV Underlayer G

To a clean 100-ml Aicello bottle, 41.38 g of PGME, 10.38 g of PGMEA, and 0.27 g of Compound 5 of Example 46 (10% in PGME) were added, then mixed for an hour prior to use. The resulting material was about 0.05% solids, resulting in a composition tailored to produce a film having a thickness of about 2 nm. When the composition was spun at 1,500 rpm for 60 seconds and baked at 160° C. for 60 seconds, the film had thickness of about 2 nm. The focus exposure matrix and an SEM image of the formed features are shown in FIG. 10.

### Example 48

### Synthesis of Compound 8

To a clean 3-neck 100 ml round bottom flask, 10.41 g of 2-(carbomethoxy) ethyltrimethoxysilane and 36.65 g of PGME were added, then set to mix for 10 minutes at room temperature. Next, 9.001 g of 0.01M HNO₃ solution was added dropwise to the solution while stirring continuously. The contents were allowed to mix for an additional 45 minutes, then refluxed at 90° C. for 11 hours in an oil bath (starting from room temperature). The product was stored in a freezer. The resulting polymer had the structure shown below.

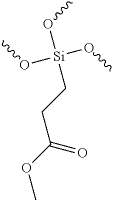

### Example 49

### Formulation of EUV Underlayer J

To a clean 100-ml Aicello bottle, 49.2484 g of PGME, 4.5476 g of Compound 1 (10% in PGME), and 1.2205 g of Compound 8 (12.4% in PGME) were added, then mixed for an hour prior to use. The material was spun at 1,500 rpm for 60 seconds then baked at 160° C. for 60 seconds. Under these conditions, with a solids composition of 1.10% solids, the material exhibited a film thickness of about 10 nm. The focus exposure matrix is shown in FIG. 11.

### Example 50

### Synthesis of Compound 11

To a clean single-neck flask, 22.48 g of PGME and 2.12 g of 1,8-diiodooctane were added then stirred at room temperature for 10 minutes. Next, 0.40 g of imidazole was added to the flask, and the mixture was allowed to stir at room temperature for 24 hours. The resulting product had about 10 percent solids. The composition was stored at room temperature. The resulting product had the structure shown below.

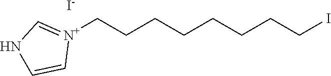 [SMILES: [I-] ; ICCCCCCCC[n+]1cc[nH]c1]

### Example 51

### Synthesis of Compound 12

In a clean tripour, 163.80 g of PGME was weighed. Then, the majority of the PGME was added to a 1 L reactor, equipped with a stir motor. The motor was set to 300 rpm. In a different tripour, 20.00 g of 2-hydroxyethylacrylate, 7.93 g of N-(2-hydroxyethyl)acrylamide, 10.76 g of styrene, and 2.26 g of azobisisobutyronitrile were weighed, then transferred to the reactor. The remaining PGME was added to the reactor to rinse. For 60 minutes, the reactor rose from room temperature to 70° C., where it remained for 16 hours. After 16 hours, the temperature was then lowered back to room temperature over 30 minutes. The product was then stored at room temperature. The product was recorded to be about 20 wt. % solids. The resulting product had the structure shown below.

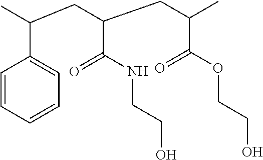 [SMILES: CC(CC(CC(C)c1ccccc1)C(=O)NCCO)C(=O)OCCO]

### Example 52

### Formulation of EUV Underlayer O

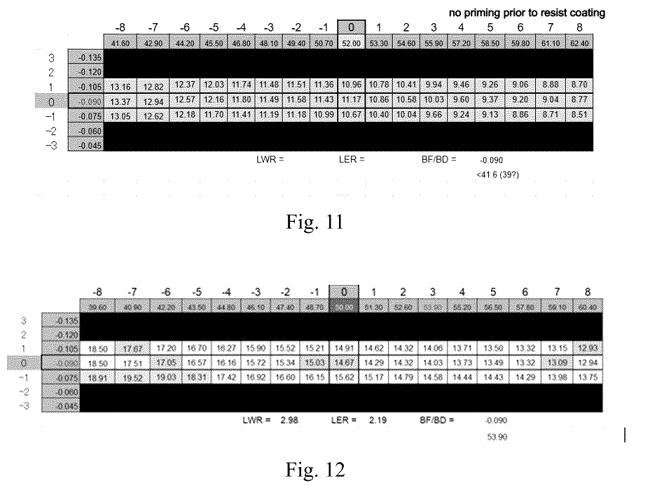

In a clean 100-ml Aicello bottle, 44.16 g of PGME, 5.03 g of PGMEA, 0.67 g of Compound 12 (20% in PGME, Brewer Science, Inc.), 0.15 g of Compound 11 (10% in PGME, Brewer Science, Inc.), and 0.17 g of PpTS solution (4% in PGME, Brewer Science, Inc.) were added. The contents were mixed for an hour prior to use and had 0.31 percent solids, yielding a composition tailored for producing a film having a thickness of about 10 nm. When spin-coated at 1,500 rpm for 60 seconds and baked 205° C. for 60 seconds, the film was recorded to be about 10 nm thick. The focus exposure matrix is shown in FIG. 12.

### Example 53

### 1a. Synthesis of 3-(8-Iodooctyl)-3-Imidazolium Iodide

To a clean single-neck flask, 22.48 g propylene glycol methyl ether (PGME) and 2.12 g 1,8-diiodooctane were added and then stirred at room temperature for 10 minutes. Next, 0.40 g imidazole was added to the flask, and the mixture was allowed to stir at room temperature for 24 hours. The resulting product, which was approximately 10% solids and whose structure is shown below, was stored at room temperature.

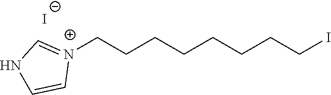

### 1b. Synthesis of 3-(5-Iodopentyl)-3-Imidazolium Iodide

To a clean single-neck flask, 17.63 g PGME and 1.63 g 1,5-diiodopentane were added then stirred at room temperature for 10 minutes. Next, 0.35 g imidazole was added to the flask, and the mixture was allowed to stir at room temperature for 24 hours. The resulting product, which was approximately 10% solids and whose structure is shown below, was stored at room temperature.

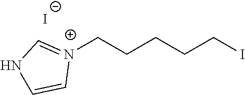 [SMILES: [I-] ; ICCCCC[n+]1cc[nH]c1]

### 1c. Synthesis of 3-ethyl-3-imidazolium iodide

To a clean single-neck flask, 20.20 g PGME and 1.57 g iodoethane were added then stirred at room temperature for 10 minutes. Next, 0.68 g imidazole was added to the flask, and the mixture was allowed to stir at room temperature for 24 hours. The resulting product, which was approximately 10% solids and whose structure is shown below, was stored at room temperature.

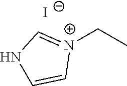

### 2. Polymer Synthesis

In a clean tri-pour, 163.80 g PGME was weighed. The majority of the PGME was added to a 1 L Huber Reactor, equipped with a stir motor. The motor was set to 300 rpm. In a different tri-pour, 20.00 g 2-hydroxyethylacrylate, 7.93 g N-(2-hydroxyethyl)acrylamide, 10.76 g styrene, and 2.26 g azobisisobutyronitrile were weighed, then transferred to the reactor. The remaining PGME was added to the reactor to rinse. The temperature program was started on the Huber, as follows: for 60 minutes, the reactor ramped from room temperature to 70° C., was held at 70° C. for 16 hours, then lowered to room temperature over the course of 30 minutes. The product was then stored at room temperature, save for a small aliquot to be submitted for GPC analysis. The product was approximately 20% solids, with the polymer structure being shown below.

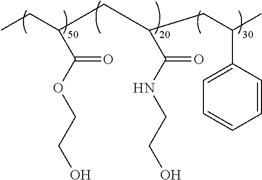

### 3. Underlayer Formulation 1 with 10% 3-(8-iodooctyl)-3-imidazolium Iodide and Polymer of Part 2

In a clean 100-ml Aicello bottle, 44.16 g PGME and 5.03 g propylene glycol monomethyl ether acetate (PGMEA) were added, followed by 0.67 g of the polymer prepared in Part 2 of this Example 53 (20% in PGME), 0.15 g the 3-(8-iodooctyl)-3-imidazolium iodide prepared in Part 1 of this Example 53 (10% in PGME), and 0.17 g pyridinium p-toluene sulfonate (PpTS as a 4% solution in PGME; PpTS obtained from Sigma-Aldrich). The contents (0.31% solids) were mixed for one hour prior to use. When spin coated at 1,500 rpm and baked 205° C. for 60 secs, the film was approximately 10 nm. The loading was 10% 3-(8-iodooctyl)-3-imidazolium iodide to polymer solids and 4% PpTS to polymer solids.

### 4. Underlayer Formulation 2 with 50% 3-(8-Iodooctyl)-3-Imidazolium Iodide and Polymer of Part 2

In a clean 100-ml Aicello bottle, 48.8495 g PGME and 5.4912 g PGMEA were added, followed by 0.1388 g of the polymer prepared in Part 2 of this Example 53 (20% in PGME), 0.3174 g of the 3-(8-iodooctyl)-3-imidazolium iodide prepared in Part 1 of this Example 53 (10% in PGME) and 0.0783 g PpTS solution (4% in PGME). The contents (0.18% solids) were mixed for one hour prior to use. When spin-coated at 1,500 rpm and baked 205° C. for 60 secs, the film was approximately 5 nm. The additive loading was 50% 3-(8-iodooctyl)-3-imidazolium iodide to polymer solids and 4% PpTS to polymer solids.

### Example 54

### 1. Polymer Synthesis

In a clean, three-neck round bottom flask equipped with a stir bar, 80.44 g PGME and 12.93 g N-(3-triethoxysilylpropyl)-4-hydroxybutyramide were added. This solution was mixed for 5 minutes. Meanwhile, in a separate vial, 6.81 g 0.01M HNO₃ were weighed and then added dropwise to the flask while stirring constantly. The flask was allowed to stir for 30 minutes at room temperature. After 30 minutes, the flask was connected to a reflux setup, equipped with nitrogen gas flow. The mixture was reacted for 10 hours at 70° C., with time to ramp up to temperature included in the 10 hours. The solution was then allowed to cool to room temperature, bottled, and stored in a freezer. A small aliquot was taken for GPC analysis. The final solution was approximately 10% solids, with the polymer structure being shown below.

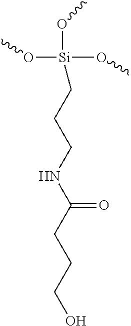

### 2. Synthesis of 3-[3-(Trimethoxysilyl)Propyl]-3iImidazolylium Iodide

In a clean, single neck round bottom flask equipped with a stir bar, 5.43 g PGME and 1.45 g 3-iodopropyltrimethoxysilane were added. This solution was mixed for 5 minutes. Meanwhile, in a separate vial, 10 g PGME and 1.03 g imidazole were shaken vigorously until all imidazole was dissolved into PGME. This mixture was then added dropwise to the flask while stirring constantly. The flask was plugged with a stopper and set to mix for 6 hours at room temperature. At the end of 6 hours, the solution was bottled and stored in the freezer. A small aliquot was taken for 1H NMR analysis. The final solution was approximately 10% solids, with the formed structure shown below.

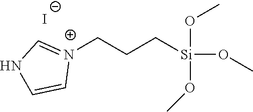

### 3. Underlayer Formulation 1

To a clean Aicello bottle, 4.2569 g of 3-[3-(trimethoxysilyl)propyl]-3iImidazolylium iodide prepared in Part 2 of this Example 54 (10% solids in PGME), 1.5799 g of the hydrolyzed product prepared in Part 1 of this Example 54 (9.04% solids in PGME), 11.297 g PpTS solution (0.2% pyridinium p-toluene sulfonate in PGME), and 63.6441 g PGME were added. The solution was mixed for one hour before use. The final % solids equaled about 0.73%, giving an approximate thickness of 10 nm after spin coating at 1500 rpm and baking at 160° C. for 60 secs. The polymer ratio of the solution was equal to 74.88%/25.12% 3-[3-(trimethoxysilyl)propyl]-3iImidazolylium iodide/hydrolyzed product, with 3.97% PpTS to polymer solids.

### 4. Underlayer Formulation 2

To a clean Aicello bottle, 0.2600 g of 3-[3-(trimethoxysilyl)propyl]-3iImidazolylium iodide prepared in Part 2 of this Example (10% solids in PGME), 2.500 g DI Water, and 22.26 g PGME were added. The solution was mixed for one hour before use. The final % solids equaled 0.1%, giving an approximate thickness of 1.2 nm after spin coating at 1,500 rpm and baking at 160° C. for 60 seconds.

### Example 55

### 1. Polymer Synthesis

To a clean single-neck flask, 0.047 g of AIBN, 0.932 g of 4-cyano-4-(((dodecylthio)carbonothioyl)thio)pentanoic acid (sold under the name BM1432 by Boron Molecular) were weighed onto weigh paper using an analytical balance and transferred to the flask. Next, 23.582 g of N-(butoxymethyl)acrylamide and 98.242 g of PGME were charged to the flask and sealed with rubber septum. The sample was mixed at 400 rpm for 5 mins prior to sparging the solution with N2 by needle. The sparged solution was immersed in a preheated oil bath at 70° C. and reacted for 24 hrs. After the allotted reaction time, the solution was allowed to cool to room temperature and down bottled into a clear Aicello bottle. Material was tested for molecular weight and residual monomer prior to formulation. The structure of the resulting polymer is shown below.

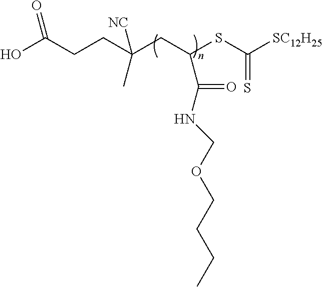

### 2. Underlayer Formulation 1

In a clean 100-ml Aicello bottle, 1.1468 g of the polymer prepared in Part 1 of this Example (20% in PGME, Brewer Science, Inc.), 0.9174 g PpTS (1% in PGME), 2.2936 g of a 1-(3-sulfopropyl)-2-vinylpyridinium hydroxide inner salt solution (SPV; 0.5% in PGME:DI_H2O 90:10), 0.2705 g deionized water, 9.4763 g PGMEA, and 85.8954 g of PGME were added. The contents (0.25% solids) were mixed for one hour prior to use. When spin coated at 1,500 rpm and baked 250° C. for 60 secs, the film was approximately 5 nm in thickness. The additive loading was 5% SPV to polymer solids and 4% PpTS to polymer solids.

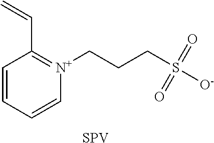

### 3. Underlayer Formulation 2

In a clean 100-ml Aicello bottle, 0.8117 g of the polymer prepared in Part 1 of this Example (20% in PGME), 0.6494 g PpTS (1% in PGME, Brewer Science, Inc.), 0.8117 g of 3-(8-iodooctyl)-3-imidazolium iodide prepared in Part 1 of Example 53 (10% in PGME), 9.9750 g PGMEA, and 87.7523 g of PGME were added. The contents (0.25% solids) were mixed for one hour prior to use. When spin coated at 1,500 rpm and baked 250° C. for 60 secs, the film was approximately 5 nm thick. The intended additive loading was 50% 3-(8-iodooctyl)-3-imidazolium iodide to polymer solids and 4% PpTS to polymer solids.

### Example 56

### Control Sample Preparation

### 1. Control Sample 1

A control sample, similar to the Example 53 formulations but without the 3-(8-iodooctyl)-3-imidazolium iodide, was prepared. In a clean 100-ml Aicello bottle, 69.882 g PGME, 9.982 g PGMEA, and 19.951 g of ethyl lactate were added, followed by 0.1787 g of the polymer prepared in Part 2 of Example 53 and 0.0070 g PpTS solids. The contents (0.1857% solids) were mixed for one hour prior to use. When spin-coated at 1,500 rpm and baked 205° C. for 60 secs, the film was approximately 5 nm. The additive loading was 0% 3-(8-iodooctyl)-3-imidazolium iodide to polymer solids and 3.77% PpTS to polymer solids.

### 2. Control Sample 2

A control sample, similar to the Example 55 formulations but without SPV or 3-(8-iodooctyl)-3-imidazolium iodide, was prepared. In a clean 100-ml Aicello bottle, 88.0326 g PGME, 9.977 g PGMEA, followed by 1.1058 g of the polymer prepared in Part 1 of Example 55 (20% in PGME) and 0.8846 g PpTS solution (1% in PGME). The contents (0.23% solids) were mixed for one hour prior to use. When spin-coated at 1,500 rpm and baked 205° C. for 60 secs, the film was approximately 5 nm. The additive loading was 0% 3-(8-iodooctyl)-3-imidazolium iodide to polymer solids, 0% SPV to polymer solids, and 4% PpTS to polymer solids.

### Example 57

### Testing of Formulations

### 1. EUV Exposure of Example 1 Formulations

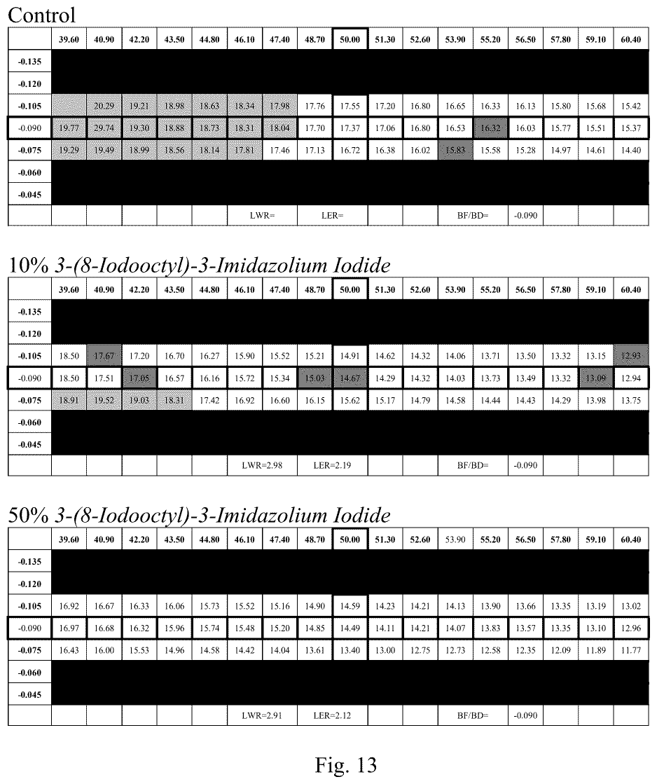

The performance of the test underlayer films prepared in Example 53, Parts 3 and 4 was compared to that of the control sample prepared in Part 1 of Example 56. After preparing the underlayer films, a 22-nm thick layer of resist (an MOR resist—YAQA from Inpria) was deposited by spin coating at 1,500 rpm, a PAB of 100° C. for 60 secs was used. Each sample was exposed to EUV radiation on an ASML NXE3400 scanner to generate P28 line/space patterns. A PEB back of 180° C. for 60 secs was carried out, and the resist was developed by solvent developer and hard baked at 250° C. for 60 secs after developer was applied. Exposure matrices were generated and are shown in FIG. 13. The dose for the two test samples was reduced to 53.9 mJ/cm² as compared to the control sample, which was 60.4 mJ/cm². Additionally, with the sample with 50% by weight loading of 3-(8-iodooctyl)-3-imidazolium iodide (Example 53, Part 4), the process window was expanded with fewer random defects, indicating the dose reduction of 3-(8-iodooctyl)-3-imidazolium iodide could be made without sacrificing the process window.

In FIG. 13, white rectangles represent good dies without defects. Light gray rectangles represent line collapse, line removal, or line breaks. Dark gray rectangles represent bridging or scumming defects.

### 2. EUV Exposure of Example 55 Formulations

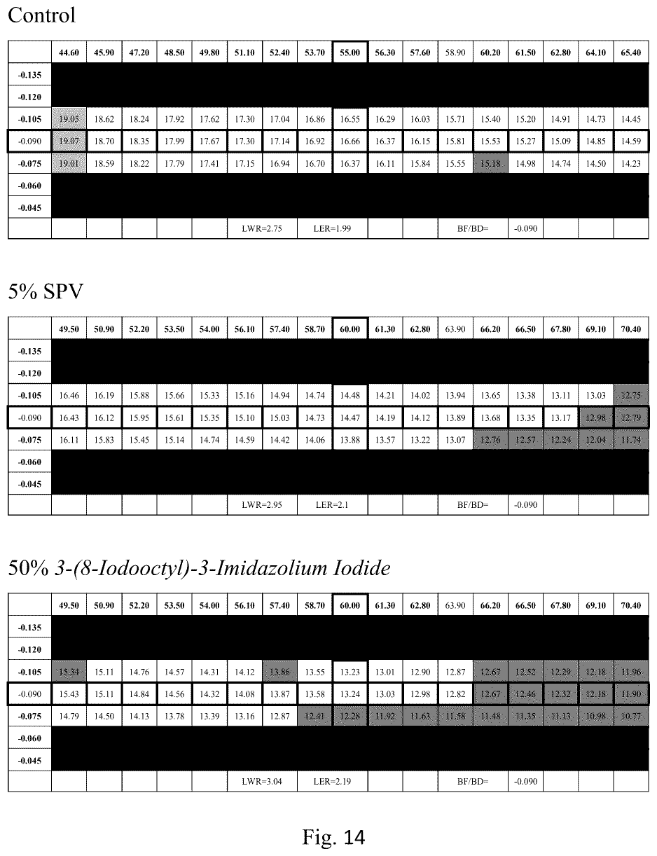

The performance of the test films prepared in Example 55, Parts 2 and 3 was compared to that of the control sample prepared in Part 2 of Example 55. Each sample was exposed to EUV radiation as described in Example 57, Part 1, and exposure matrices were generated. See FIG. 14, where shaded rectangles represent bridging or scumming. Both salts (SPV and 3-(8-iodooctyl)-3-imidazolium iodide) resulted in significant dose reduction relative to the baseline formulation. Specifically, the Example 55, Part 2 formulation resulted in ˜5 mJ/cm² dose improvement at about 63.3 mJ/cm² (vs. 68 mJ/cm² for the control), and the Example 55, Part 3 formulation resulted in 12 mJ/cm² improvement at about 56.1 mJ/cm². An increase in LWR and LER was observed as expected with lower dose. The control had an LWR/LER (nm) of 2.75/1.99, while the Example 55, Part 2 formulation was 2.95/2.10, and the Example 55, Part 3 formulation was 3.04/2.19.

1. A method of forming a structure, said method comprising:
applying a composition to a stack so as to form an underlayer on the stack, said composition comprising a solvent system having one or both of the following dispersed or dissolved therein:
(1) about 5% by weight or more of an ionic compound, ionic moiety, or both, said % by weight being based on the total solids in the composition taken as 100% by weight,
wherein when said ionic compound or ionic moiety comprises 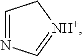
the following structure is not present 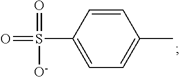
or
(2) a pre-ionic compound capable of generating (1) upon heating;
forming a metal oxide photoresist layer on said underlayer; and
subjecting at least a portion of said photoresist layer to EUV radiation.

2. The method of claim 1, wherein said pre-ionic compound is capable of generating (1) if heated at a temperature of about 140° C. for about 60 seconds.

3. The method of claim 1, wherein said photoresist layer comprises a metal oxide.

4. The method of claim 1, wherein said composition comprises (2) and said pre-ionic compound comprises one or both of:
(a) a polymer comprising a first monomer comprising a tertiary amine and a second monomer comprising a displaceable electrophile; or
(b) a first polymer comprising a tertiary amine and a second polymer different from said first polymer and comprising a displaceable electrophile.

5. The method of claim 4, wherein said tertiary amine is part of a structure chosen from 4-vinylpyridine, 2-vinylpyridine, 2-(dimethylamino)ethyl methacrylate, 1-vinylimidazole, or combinations thereof.

6. The method of claim 4, wherein at least one of the following is true:
said second monomer is chosen from glycidyl acrylate, glycidyl methacrylate, 4-glycidyloxystyrene, or combinations thereof; or
said second polymer comprises recurring monomers chosen from glycidyl acrylate, glycidyl methacrylate, 4-glycidyloxystyrene, or combinations thereof.

7. The method of claim 4, wherein:
(i) when said pre-ionic compound comprises (a), said polymer further comprises a third monomer without a tertiary amine and without a displaceable electrophile; and
(ii) when said pre-ionic compound comprises (b):
at least one of said first or second polymer comprises a third monomer without a tertiary amine and without a displaceable electrophile; and/or
said composition further comprises a third polymer, said third polymer including monomers without a tertiary amine and without a displaceable electrophile.

8. The method of claim 7, wherein said third monomer is chosen from substituted and unsubstituted styrene-containing monomers, methyl acrylate, hydroxyethyl methacrylate, hydroxyethyl acrylate, hydroxypropyl methacrylate, benzyl methacrylate, n-butyl methacrylate, methyl methacrylate, tert-butyl methacrylate, 2-(dimethylamino)ethyl methacrylate, N-(butoxymethyl)acrylamide, or combinations thereof.

9. The method of claim 4, wherein the molar ratio of tertiary amine to displaceable electrophile is about 2:1 to about 1:20.

10. The method of claim 7, wherein said third monomer is present at a level of about 3 mol % to about 50 mol %, based on the total moles of tertiary amine and displaceable electrophile.

11. The method of claim 1, wherein said applying a composition comprises heating a layer of said composition to form said underlayer, and forming an ionic compound, ionic moiety, or both during said heating.

12. The method of claim 4, wherein said applying a composition comprises heating a layer of said composition to form said underlayer, and during said heating said tertiary amine reacts with said displaceable electrophile to form an ionic compound, ionic moiety, or both.

13. The method of claim 4, wherein at least one of the following is true:
said pre-ionic compound comprises (a), said first monomer comprises vinylpyridine, and said second monomer comprises glycidyl methacrylate; or
said pre-ionic compound comprises (b), said first polymer comprises vinylpyridine, and said second polymer comprises glycidyl methacrylate.

14. The method of claim 1, said stack comprising:
a substrate having a surface; and
optionally one or more intermediate layers on said surface, there being an uppermost intermediate layer on said surface if one or more intermediate layers are present, said underlayer being on said uppermost intermediate layer, if present, or on said surface, if no intermediate layers are present, and method further comprising:
forming a pattern in said photoresist layer after said subjecting said photoresist layer to EUV radiation; and
transferring said pattern:
to said underlayer;
to said intermediate layers, if present; and
to said substrate.

15. The method of claim 14, wherein said subjecting said photoresist layer to EUV radiation comprises using an exposure dose, and at least one of the following is true:
said exposure dose is about 5 mJ/cm² to about 80 mJ/cm²; or
said exposure dose is about 4 mJ/cm² or more below the exposure dose needed by a different layer that does not include (1) or (2) but is otherwise chemically identical to said underlayer.

16. A structure comprising:
a substrate having a surface;
optionally one or more intermediate layers on said substrate surface, there being an uppermost intermediate layer on said substrate surface, if one or more intermediate layers are present;
an underlayer on said substrate surface, or on said uppermost intermediate layer, if present, said underlayer comprising one or both of:
(1) about 5% by weight or more of an ionic compound, ionic moiety, or both, said % by weight being based on the total weight of the underlayer taken as 100% by weight,
wherein when said ionic moiety comprises 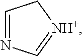
the following structure is not present 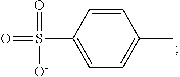
or
(2) a polymer network comprising tertiary amines reacted with respective displaceable electrophiles to form crosslinks, said tertiary amines including respective positively charged nitrogen atoms and said crosslinks including negatively charged oxygen atoms; and
a metal oxide photoresist on said underlayer.

17. The structure of claim 16, wherein said tertiary amine is part of a structure chosen from 4-vinylpyridine, 2-vinylpyridine, 2-(dimethylamino)ethyl methacrylate, 1-vinylimidazole, or combinations thereof.

18. The structure of claim 16, wherein said displaceable electrophile is part of a structure chosen from glycidyl acrylate, glycidyl methacrylate, 4-glycidyloxystyrene or combinations thereof.

19. The structure of claim 16, wherein said polymer network further comprises a monomer chosen from substituted and unsubstituted styrene-containing monomers, methyl acrylate, hydroxyethyl methacrylate, hydroxyethyl acrylate, hydroxypropyl methacrylate, benzyl methacrylate, n-butyl methacrylate, methyl methacrylate, tert-butyl methacrylate, 2-(dimethylamino)ethyl methacrylate, N-(butoxymethyl)acrylamide, or combinations thereof.

20. The structure of claim 19, wherein said monomer is present at a level of about 3 mol % to about 50 mol %, based on the total moles of tertiary amine and displaceable electrophile.

21. The structure of claim 16, wherein the molar ratio of tertiary amine to displaceable electrophile is about 2:1 to about 1:20.
